(19) United States
(12) Patent Application Publication
(10) Pub. No.: US 2012/0125781 A1
(43) Pub. Date: May 24, 2012

(54) COMPOSITIONS AND METHODS FOR SYNTHESIS OF HYDROGEN FUEL

(76) Inventors: Jin Zhong Zhang, Santa Cruz, CA (US); Abraham Wilcott, Santa Cruz, CA (US); Jennifer Hensel, Santa Cruz, CA (US); Tzarara Lopez-Luke, Santa Cruz, CA (US); Yat Li, Santa Cruz, CA (US)

(21) Appl. No.: 12/998,867

(22) PCT Filed: Dec. 10, 2009
(86) PCT No.: PCT/US2009/006508

§ 371 Date: Feb. 1, 2012

Related U.S. Application Data
(60) Provisional application No. 61/201,440, filed on Dec. 10, 2008.

(51) Int. Cl. C25B 1/02; C25B 9/04; H01L 31/0272; H01L 31/0224

(52) U.S. Cl. 205/340; 136/252; 204/242; 136/260

(57) ABSTRACT

The invention provides new methods and compositions for synthesizing hydrogen fuel using simple and inexpensive materials.

This invention was made partly using funds from US Department of Energy (USDOE) research grant number DE-FG02-05ER46232-A002, and the United States National Science Foundation, Major Research Instrumentation (MRI) Program grant number CHE-0521569. The US Federal Government has certain rights to this invention.

### FIELD OF THE INVENTION

The invention is drawn to novel compositions and methods for generating an electric current. The invention also provides novel compositions and methods for generating hydrogen as a fuel.

### BACKGROUND OF THE INVENTION

In recent years there is an increasing interest to find sustainable alternative energy (SAE) sources due to the heightening cost of fossil fuels and the detrimental effects of global climate change. Photovoltaic (PV) cells have received significant attention due to the limitless influx of photons from the sun. Recent market energy analysis is predicting energy parity between conventional energy production and PV costs in cents per kilowatt hour (cents/kWh) in only 5-8 years (LoPiccolo, P. Solid State Technology 2007, 50, 2). Efficiency of silicon solar cells have attained a solar conversion efficiency of 20%, however the manufacturing process is very expensive and involves the use of toxic chemicals inherit in the semiconductor industry.

To date, there have been reports of two types of solar cells based on nanostructured semiconductor materials: the Grätzel solar cell, based on dye sensitized nanoporous semiconductor thin films and the quantum dot solar cell, based on composite films of semiconductor nanoparticles (CdSe) and conjugated polymers studied by Greenham et al. (see, for example, O'Regan, B.; Gratzel, M. Nature 1991, 353, 737; Greenham, N.C.; Peng, X. G.; Alivisatos, A. P. Phys. Rev. B 1996, 54, 17628). Grätzel's initial report in 1991 presented a nanocrystalline dye-sensitized solar cell converting light to electrical energy with an efficiency of 7% (O'Regan et al. supra). The dye-sensitized solar cell (DSSC) consists of TiO₂ nanoparticles acting as a highly porous wide-bandgap semiconductor electron acceptor layer. In the DSSC visible light absorbing dye molecules adsorbed onto the TiO₂ surface act as the sensitizer to harvest more of the solar flux. Under irradiation, the photoexcited dye molecules inject electrons to the TiO₂ layer that are transported through the porous TiO₂ layer and collected by a conductive fluorine doped SnO₂ layer on the glass surface. The oxidized dye is regenerated by a liquid electrolyte, with the highest reported efficiency of about 10%. Greenham et al. (supra) investigated the processes of charge separation and transport in the interface between a conjugated polymer and semiconductor nanocrystal as a hybrid organic-inorganic system. A quantum efficiency of up 12% has been reported with a high concentration of nanocrystals, where both nanocrystals and polymers provide continous pathways to the electrodes (Greenham et al. supra). The absorption, charge separation and transport properties of the composities were found to be a function of the size, material and the surface ligands of the nanocrystals utilized.

TiO₂ and ZnO nanoparticles represent good examples of nanocrystalline materials used for potentially low cost PV devices for energy conversion, as an alternative to silicon solar cell technology and for photocatalysis (Belver, C.; Bellod, R.; Fuerte, A.; Fernandez-Garcia, M. Applied Catalysis B-Environmental 2006, 65, 301; Gregg, B. A. J. Phys. Chem. B 2003, 107, 4688; Hagfeldt, A.; Gratzel, M. Accounts of Chemical Research 2000, 33, 269; Kamat, P. V. J. Phys. Chem. C 2007, 111, 2834; Lokhande, C. D.; Park, B. O.; Park, H. S.; Jung, K. D.; Joo, O. S. Ultramicroscopy 2005, 105, 267; Smestad, G. P.; Spiekermann, S.; Kowalik, J.; Grant, C. D.; Schwartzberg, A. M.; Zhang, J.; Tolbert, L. M.; Moons, E. Solar Energy Materials Solar Cells 2003, 76, 85; Khaselev, O.; Turner, J. A. Science 1998, 280, 425; and Parsons, C. A.; Peterson, M. W.; Thacker, B. R.; Turner, J. R.; Nozik, A. J. J. Phys. Chem. 1990 94, 3381). Titanium dioxide (TiO₂), or titania, exists in three crystalline phases: anatase, rutile and brookite. Anatase and rutile have found uses mainly in PV cells, photoelectrochemical cells (PEC), and photocatalysis applications (Colon, G.; Maicu, M.; Hidalgo, M. C.; Navio, J. A. Applied Catalysis B-Environmental 2006, 67, 41; Kim, Y. G.; Walker, J.; Samuelson, L. A.; Kumar, J. Nano Letters 2003, 3, 523; Toyoda, T.; Tsuboya, I.; Shen, Q. Materials Science & Engineering C-Biomimetic Supramolecular Systems 2005, 25, 853; and Wang, J. W.; Zhu, W.; Zhang, Y. Q.; Liu, S. X. J. Phys. Chem. C 2007, 111, 1010). On the contrary, the brookite phase has not received similar attention, perhaps because it is the most difficult to prepare in the form of a thin film (Djaoued, Y.; Bruning, R.; Bersani, D.; Lottici, P. P.; Badilescu, S. Mater. Letters 2004, 58, 2618). Titania has a wide band gap (3.2 eV) and absorbs only 5% of the solar spectrum, resulting in poor conversion efficiency in solar cell applications. Non metal-doped TiO₂ nanoparticles and nanotubes have been shown to produce electronic states in the TiO₂ bandgap, thereby extending photoresponse to the visible region and improving photoactivity (Huang, D. G.; Liao, S. J.; Liu, J. M.; Dang, Z.; Petrik, L. J. Photochem. Photobio. A-Chem. 2006, 184, 282; Huang, L. H.; Sun, Z. X.; Liu, Y. L. J. Ceramic Soc. Jap. 2007, 115, 28; Nishijima, K.; Naitoh, H.; Tsubota, T.; Ohno, T. J. Ceramic Soc. Jap. 2007, 115, 310). Recent studies of TiO₂:N and ZnO:N have found success in narrowing the bandgap and increasing light harvesting efficiency with nitrogen doping, and research has been focusing on the resulting photoelectro-chemical properties and photocatalytic activity for SAE production. Several different synthesis protocols have been developed to produce TiO₂:N. The usual doping process involves using ammonia as a nitrogen source by sol-gel, thermal, or hydrothermal chemical methods (Moribe, S.; Ikoma, T.; Akiyama, K.; Zhang, Q. W.; Saito, F.; Tero-Kubota, S. Chem. Phys. Lett. 2007, 436, 373; Sathish, M.; Viswanathan, B.; Viswanath, R. P.; Gopinath, C. S. Chem. Mater. 2005, 17, 6349; Beranek, R.; Kisch, H. Electrochem. Commun. 2007, 9, 761; Chen, H. Y.; Nambu, A.; Wen, W.; Graciani, J.; Zhong, Z.; Hanson, J. C.; Fujita, E.; Rodriguez, J. A. J. Phys. Chem. C 2007, 111, 1366; and Yin, S.; Ihara, K.; Aita, Y.; Komatsu, M.; Sato, T. J. Photochem. Photobio. A-Chem. 2006, 179, 105).

An alternative method to obtain TiO₂:N involves using hexamethylenetetramine (HMT) by chemical and mechanochemical processes. The resulting effect on crystalline phase composition showed increased photocatalytic activity and photovoltaic properties, with specific morphologies produced (Wu, J. M.; Qi, B. J. Phys. Chem. C 2007, 111, 666; Yin, S.; Komatsu, M.; Zhang, Q. W.; Saito, F.; Sato, T. J. Mater. Science 2007, 42, 2399). Nitrogen doping within TiO₂ can be interstitial or substitutional, with the latter being more effective, resulting in mixing of N 2p states with O 2p states, and contributing to the bandgap narrowing. Different techniques have been used to study N doped TiO₂ crystallographically, including XPS, EPR, Raman spectroscopy and XRD and absorption spectroscopy (see Chen and Burda J. Phys. Chem. B 2004, 108, 15446; Reyes-Garcia et al. J. Phys. Chem. C 2007, 111, 2738; and Wan et al. Appl. Surf. Sci. 2007, 253, 4764). Theoretical studies have supported the visible absorption and the resulting yellowish color of TiO₂:N thin films and powders (see, for example, Asahi, R.; Morikawa, T.; Ohwaki, T.; Aoki, K.; Taga, Y. Science 2001, 293, 269; Di Valentin, C.; Pacchioni, G.; Selloni, A.; Livraghi, S.; Giamello, E. J. Phys. Chem. B 2005, 109, 11414; Chen and Burda supra; Reyes-Garcia et al. supra; Wan et al. supra; Livraghi, S.; Paganini, M. C.; Giamello, E.; Selloni, A.; Di Valentin, C.; Pacchioni, G. J. Am. Chem. Soc. 2006, 128, 15666; and Burda, C.; Lou, Y. B.; Chen, X. B.; Samia, A. C. S.; Stout, J.; Gole, J. L. Nano Letters 2003, 3, 1049).

Alternative techniques to increase the photoresponse besides doping include the utilization of tunable narrow bandgap semiconductor nanoparticles or quantum dots (QDs) such as CdS, CdSe, and CdTe to sensitize wide bandgap semiconductors such as the metal oxides, e.g. TiO₂ and ZnO (Leschkies, K. S.; Divakar, R.; Basu, J.; Enache-Pommer, E.; Boercker, J. E.; Carter, C. B.; Kortshagen, U. R.; Norris, D. J.; Aydil, E. S. Nano Letters 2007, 7, 1793; Levy-Clement, C.; Tena-Zaera, R.; Ryan, M. A.; Katty, A.; Hodes, G. Adv. Mater. 2005, 17, 1512; Robel, I.; Kuno, M.; Kamat, P. V. J. Am. Chem. Soc. 2007, 129, 4136; and Somasundaram, S.; Chenthamarakshan, C. R.; de Tacconi, N. R.; Ming, Y.; Rajeshwar, K. Chem. Mater. 2004, 16, 3846). QDs with their large extinction coefficient strongly absorb visible light and inject electrons into the conduction band of metal oxides, and thereby contribute to increased solar energy conversion. Attachment of CdSe QDs to nanocrystalline TiO₂ has been shown to be successful with an immersion method using a bimolecular linker (Robel, I.; Subramanian, V.; Kuno, M.; Kamat, P. V. J. Am. Chem. Soc. 2006, 128, 2385). Sonochemical, photodeposition, and chemical bath deposition of CdSe on TiO₂ nanoparticles and nanotubes has also been studied for photocatalysis applications (Liu, H. Y.; Gao, L. J. Am. Ceramic Soc. 2005, 88, 1020; Nguyen, V. N. H.; Amal, R.; Beydoun, D. J. Photochem. Photobio. A-Chem. 2006, 179, 57; and Niitsoo, O.; Sarkar, S. K.; Pejoux, C.; Ruhle, S.; Cahen, D.; Hodes, G. J. Photochem. Photobio. A-Chem. 2006, 181, 306). However, the use of QDs to improve TiO₂ based solar cell efficiency is still an area of active exploration.

Hydrogen is very attractive as a clean fuel due to its high energy density and benign chemical byproduct, water (Bak, T.; Nowotny, J.; Rekas, M.; Sorrell, C. C. Int. J. Hydrogen Energy 2002, 27, (10), 991-1022; Yilanci, A.; Dincer, I.; Ozturk, H. K. Prog. Energ. Combust. 2009, 35, (3), 231-244). Producing hydrogen from water splitting using solar energy based on photoelectrochemical (PEC) cells, photovoltaic cells and photocatalysis is highly desirable because it leaves less of a carbon footprint and the resources used, water and sunlight, are abundant (Bak et al. supra; Yilanci et al. supra; Li, Y.; Zhang, J. Z. Laser Photonics Rev. 2009, in press; Fujishima, A.; Honda, K. Nature 1972, 238, (5358), 37-38; Heller, A. Science 1984, 223, (4641), 1141-1148; Murphy, A. B. B., P. R. F.; Randeniya, L. K.; Plumb, I. C.; Grey, I. E.; Horne, M. D.; Glasscock, J. A. Int. J. Hydrogen Energy 2006, 31, 1999-2017; Chen, D.; Gao, Y. F.; Wang, G.; Zhang, H.; Lu, W.; Li, J. H. J. Phys. Chem. C 2007, 111, 13163-13169; Liu, J.; Cao, G.; Yang, Z.; Wang, D.; Dubois, D.; Zhou, X.; Graff, G. L.; Pederson, L. R.; Zhang J. G. Chem. Sus. Chem. 2008, 1, 676-697; Khaselev, O.; Turner, J. A. Science 1998, 280, (5362), 425-427; and Osterloh, F. E. Chem. Mater. 2008, 20, 35-54). A conventional PEC cell is established with a semiconductor photoanode and a platinum electrode as the cathode in an electrolyte solution. Electrons and holes are created when a semiconductor anode absorbs light. The depletion layer formed at the semiconductor-electrolyte interface leads to energy band bending that facilitates separation of photogenerated electrons and holes. The electrons and holes perform chemical redox reactions at the semiconductor photoanode and the platinum cathode (Bak et al. supra; Fujishima and Honda supra). Typically, the reaction is the splitting of water, 2H₂O→2H₂+O₂, but hydrogen can also be generated by the use of sacrificial electrolytes, such as Na₂S and Na₂SO₃ (Rao, N. N.; Dube, S. Int. J. Hydrogen Energy 1996, 21, (2), 95-98).

Wide bandgap semiconductors such as TiO₂, ZnO and WO₃ have been demonstrated as promising candidates for photoanodes due to their energy band position, thermal and chemical stability in solution (Bak et al. supra; Fujishima and Honda supra; and Yang, X.; Wolcottt, A.; Wang, G.; Sobo, A.; Fitzmorris, R. C.; Qian, F.; Zhang, J. Z.; Li, Y. Nano Lett. 2009, 9, (6), 2331-2336). However, they are not ideal due to their weak absorption of visible light (Murphy et al. supra). Doping of such wide bandgap metal oxides is one of the most promising approaches to increasing their visible light absorption. Asahi et al. first reported N-doped TiO₂ films prepared by sputtering that showed noticeable visible light absorption at wavelengths less than 500 nm due to the bandgap narrowing by mixing of N 2p states with O 2p states (Asahi, R.; Morikawa, T.; Ohwaki, T.; Aoki, K.; Taga, Y. Science 2001, 293, (5528), 269-271). On the other hand, sensitizing metal oxides with small bandgap semiconductors is another attractive method for increasing their visible light absorption, which has recently been demonstrated for ZnO and TiO₂ (Tak, Y.; Hong, S. J.; Lee, J. S.; Yong, K. Cryst. Growth Des. 2009, 9, (6), 2627-2632; Lee, Y. L.; Chi, C. F.; Liau, S. Y. Chem. Mater. 2009, in press). When the conduction band edge of a small bandgap semiconductor is higher than that of the metal oxide, the photogenerated electrons in the small bandgap semiconductor can be injected to the conduction band of the metal oxide. To date, both sensitization and doping of metal oxide nanostructures have been explored separately for solar energy conversion applications, yet little work has been done on combining the two approaches.

There is therefore a need in the art for compositions and methods for synthesis of hydrogen that is both relatively inexpensive and uses relatively simple compositions and components.

### SUMMARY OF THE INVENTION

The invention provides a thin film structure comprising a conducting substrate, a thin layer comprising nanocrystalline metal oxide doped with nitrogen thereon, and further comprising a semiconductor quantum dot and a linker thereon said thin layer of nanocrystalline metal oxide. In one preferred embodiment the conducting substrate is selected from the group consisting of indium tin oxide and fluorine tin oxide. In another preferred embodiment the nanocrystalline metal oxide is selected from the group consisting of titanium dioxide, tungsten oxide, and zinc oxide. In yet another preferred embodiment the semiconductor quantum dot is selected from the group consisting of cadmium selenium and cadmium telluride. In a still further preferred embodiment the linker is selected from the group consisting of thioglycolic acid (TGA), mercapto-propanoic acid (MPA), and cysteine and links the semiconductor quantum dot with the conducting substrate.

The invention also provides a photovoltaic cell comprising the thin film structure as disclosed herein. In one preferred embodiment, the photovoltaic cell has a power conversion efficiency of between 1·10⁻³ and 5 η %. In a more preferred embodiment the power conversion efficiency is of between 5·10⁻³ and 1 η %. In another preferred embodiment the photovoltaic cell has an incident photon to current conversion efficiency (IPCE) of between 1% and 99.5%. In a more preferred embodiment, the IPCE is of between 13% and 95%. In a still further preferred embodiment the IPCE is of between 25% and 90%. In a yet further preferred embodiment the IPCE is of between 50% and 85%.

The invention further provides a hydrogen synthesis system comprising the photovoltaic cell comprising the thin film structure as disclosed herein. In one embodiment the hydrogen synthesis system further comprises hydrogen storage means wherein the hydrogen is stored therein. In a preferred embodiment the hydrogen storage means is selected from the group consisting of a cylinder, a tank, a gas tank, a vessel comprising a fluid in which the hydrogen is dissolved or dispersed under pressure, and the like. In another preferred embodiment, the hydrogen is stored as a phase selected from the group consisting of a gas, a liquid, and as a liquid or gas in a composition, the composition comprising a plurality of cavities, and the like.

The invention also provides a method for generating an electric current, the method comprising the steps of (i) providing a conducting substrate; (ii) doping a nanocrystalline metal oxide with nitrogen; (iii) depositing said crystalline metal oxide doped with nitrogen upon said conducting substrate; (iv) providing a semiconductor quantum dot; (v) linking said semiconductor quantum dot to said conducting substrate using a linker; (vi) irradiating the surface of said conducting substrate with a photon source thereby creating or inducing an electric current through the conducting substrate; the method thereby generating an electric current. In a preferred embodiment the photon source is selected from the group consisting of a tungsten lamp, a fluorescent lamp, an arc lamp, a laser, a light-emitting diode, a liquid crystal diode, a radionuclide, the sun, a gamma ray, a fluorescent molecule composition, and the like. In one preferred embodiment the conducting substrate is selected from the group consisting of indium tin oxide and fluorine tin oxide. In another preferred embodiment the crystalline metal oxide is selected from the group consisting of titanium dioxide, tungsten oxide, and zinc oxide. In yet another preferred embodiment the semiconductor quantum dot is cadmium selenium and cadmium telluride. In a still further preferred embodiment the linker is selected from the group consisting of thioglycolic acid (TGA), mercaptopropanoic acid (MPA), and cysteine and links the semiconductor quantum dot with the conducting substrate.

In one embodiment the method herein disclosed comprises using a photon source wherein the photons from the photon source have power intensity of between 1 and 10000 mW/cm². In a preferred embodiment the photons from the photon source have power intensity of between 10 and 1000 mW/cm². In a more preferred embodiment the photons from the photon source have power intensity of between 25 and 250 mW/cm². In a yet more preferred embodiment the photons from the photon source have power intensity of 100 mW/cm². In an alternative more preferred embodiment the photons from the photon source have power intensity of 27 mW/cm². For example, the photons from the photon source can have a power intensity of 1, 2, 2.5, 3, 4, 5, 6, 7, 8, 9, 10, 12.5, 15, 17.5, 20, 25, 27, 30, 35, 40, 45, 50, 55, 60, 65, 70, 75, 80, 85, 90, 95, 100, 110, 120, 130, 140, 150, 160, 170, 180, 190, 200, 250, 300, 350, 400, 450, 500, 550, 600, 650, 700, 750, 800, 850, 900, 950, 1000, 2000, 3000, 4000, 5000, 6000, 7000, 8000, 9000, 10000 mW/cm² .

The invention also provides a method for generating hydrogen, the method comprising the steps of (i) providing a conducting substrate; (ii) doping a crystalline metal oxide with nitrogen; (iii) depositing said nanocrystalline metal oxide doped with nitrogen upon said conducting substrate; (iv) providing a semiconductor quantum dot; (v) linking said semiconductor quantum dot to said conducting substrate using a linker; (vi) providing a hydrogen source in contact with the opposing surface of said conducting substrate; (vii) irradiating the surface of said conducting substrate with a photon source thereby creating or inducing an electric current through the conducting substrate; (viii) allowing the electric current to electrolyze the hydrogen source, thereby producing hydrogen; the method thereby generating hydrogen. In a preferred embodiment the photon source is selected from the group consisting of a tungsten lamp, a fluorescent lamp, an arc lamp, a laser, a light-emitting diode, a liquid crystal diode, a radionuclide, the sun, a gamma ray, a fluorescent molecule composition, and the like. In one preferred embodiment the conducting substrate is selected from the group consisting of indium tin oxide and fluorine tin oxide. In another preferred embodiment the nanocrystalline metal oxide is selected from the group consisting of titanium dioxide, tungsten oxide, and zinc oxide. In yet another preferred embodiment the semiconductor quantum dot is selected from the group consisting of cadmium selenium and cadmium telluride. In a still further preferred embodiment the linker is selected from the group consisting of thioglycolic acid (TGA), mercaptopropanoic acid (MPA), and cysteine and links the semiconductor quantum dot with the conducting substrate. In a preferred embodiment the hydrogen source is a compound comprising hydrogen, carbon, oxygen, or any combination thereof. In a more preferred embodiment the hydrogen source is selected from the group consisting of methanol, ethanol, water, formic acid, and an amine compound. For example, the hydrogen source can be an alcohol, an organic acid, or an organic waste compound, such as residual waste from households, commerce, and/or industry.

In one embodiment the method herein disclosed comprises using a photon source wherein the photons from the photon source have power intensity of between 1 and 10000 mW/cm². In a preferred embodiment the photons from the photon source have power intensity of between 10 and 1000 mW/cm². In a more preferred embodiment the photons from the photon source have power intensity of between 25 and 250 mW/cm². In a yet more preferred embodiment the photons from the photon source have power intensity of 100 mW/cm². In an alternative more preferred embodiment the photons from the photon source have power intensity of 27 mW/cm². For example, the photons from the photon source can have a power intensity of 1, 2, 2.5, 3, 4, 5, 6, 7, 8, 9, 10, 12.5, 15, 17.5, 20, 25, 27, 30, 35, 40, 45, 50, 55, 60, 65, 70, 75, 80, 85, 90, 95, 100, 110, 120, 130, 140, 150, 160, 170, 180, 190, 200, 250, 300, 350, 400, 450, 500, 550, 600, 650, 700, 750, 800, 850, 900, 30 950, 1000, 2000, 3000, 4000, 5000, 6000, 7000, 8000, 9000, 10000 mW/cm² .

### BRIEF DESCRIPTION OF THE DRAWINGS

FIG. 1. Photovoltaic schematic of TiO₂:N-TGA-CdSe cells in (a) Na₂S electrolyte (b) solid. (c) Representation of TiO₂-3 and TiO₂-4 nanoparticles functionalized with CdSe linked with a bifunctional molecule TGA, in a porous film (using hexamethylenetetramine (HMT) and HMT+polyethylene glycol (PEG) in the TiO₂ synthesis respectively). d) Representation of TiO₂-1-TGA-CdSe film (without nitric acid) and TiO₂-2-TGA-CdSe film (using nitric acid in the TiO₂ synthesis) with low porosity.

FIG. 2. (a)) X-ray photoelectron spectroscopy (XPS) Spectra of nitrogen doped TiO₂-3 film on SnO₂:F substrate showing C, N, Ti, O and Sn spectra peaks. (b) A detailed N1s XPS band.

FIG. 3. X-ray powder diffraction (XRD) patterns of TiO₂ films on the SnO₂:F substrate prepared by sol-gel method, using different chemicals in the TiO₂ synthesis, annealed at 550° C. during 1.5 h in a heat gun, for (a) TiO₂-1 film (without nitric acid), (b) TiO₂-2 film (using nitric acid), (c) TiO₂-3 film (using nitric acid and HMT) and (d) TiO₂-4 (using nitric acid, HMT and PEG). The phases found in the films are anatase, rutile and brookite marked by A, R and B respectively. SnF represents the crystal phase of the conductive glass (SnO₂:F).

FIG. 4. TiO₂ films Raman Spectra of (a) TiO₂-1 (without nitric acid, HMT nor PEG), (b) TiO₂-3 (using nitric acid and HMT in the synthesis), (c) TiO₂-4 (using nitric acid, HMT and polyethylene glycol (PEG) in the synthesis).

FIG. 5. Atomic force microscopy (AFM) images of (left) Nitrogen doped TiO₂-3 thin film (175 nm) and (right) N doped TiO₂-3 nanoparticles linked to TGA-CdSe nanoparticles (film thickness ˜1100 nm).

FIG. 6. Representative transmission electron microscopy (TEM) image of CdSe quantum dots showing an average particle size around 3.5 nm.

FIG. 7. UV-VIS absorption spectra of the films (a) TiO₂-1 (without nitric acid), (b) TiO₂-2 (using nitric acid in the synthesis without HMT), (c) TiO₂-3 film (synthesized with nitric acid and HMT), (d) TiO₂-4 film (synthesized with HMT and PEG) and (e) TiO₂-3 -TGA-CdSe film. The blank was the substrate of SnO₂:F (of the conductive glass).

FIG. 8. UV-VIS absorption spectra of (a) CdSe nanoparticles and (b) Photoluminescence (PL) spectra of CdSe nanoparticles in toluene excited at 390 nm. (c) PL of TiO₂-3 film doped with nitrogen and sensitized with CdSe QDs.

FIG. 9. I-V characteristic of (a) TiO₂-1-TGA-CdSe thick film, (b) TiO₂-3-TGA-CdSe thin film and (c) TiO₂-3-TGA-CdSe thick film. Using 1 M Na₂S, excited with halogen lamp with incident light intensity of Iᵢ=27 mW/cm².

FIG. 10. IPCE % of the different cells with (∘) TiO₂-3 film without QD sensitization, (this curve is amplified 10×), (▪) TiO₂-1-TGA-CdSe film with QD sensitization and () TiO₂-3-TGA-CdSe film with QD sensitization.

FIG. 11. IPCE % of the solid state cell of TO₂-3-TGA-CdSe film in open air conditions. Inset is a UV-vis and PL spectra of CdSe QDs in toluene with an average size of 4.6 nm utilized to sensitize the nitrogen doped TiO₂-3 film.

FIG. 12. Schematic electronic band structure of 3.5 nm CdSe with an effective bandgap of 2.17 eV and nanocrystalline TiO₂:N with a 3.2 eV bandgap, associated with normal TiO₂ and a N dopant state approximately 1.14 eV above the valence band; as reported by Asahi et al (as denoted by asterisk *; see Asahi, R.; Morikawa, T.; Ohwaki, T.; Aoki, K.; Taga, Y. Science 2001, 293, 269). Different electron and hole creation, relaxation, and recombination pathways are illustrated, including (A) photoexcitation of electron from the valence band (VB) to the conduction band (CB) of TiO₂, (B) transition or photoexcitation of electron from the N energy level to the CB of TiO₂, (C) recombination of electron in the CB of TiO₂ with hole in N energy level, (D) electron transfer or injection from the CB of CdSe QD to the CB of TiO₂, and (E) hole transfer from the VB of CdSe QD to the N energy level. Note that not all these processes can happen simultaneously and many of these are competing processes.

FIG. 13. UV-VIS absorption spectra of TiO₂, TiO₂:N, CdSe—TiO₂ and CdSe—TiO₂:N nanoparticle films.

FIG. 14. Linear sweep voltammograms collected from a) TiO₂; b) TiO₂:N; c) CdSe—TiO₂; and d) CdSe—TiO₂:N nanoparticle films, at a scan rate of 10 mV/s in dark and with light illumination of 100 mW/cm².

FIG. 15. Proposed model for the electron transfer at CdSe/TiO₂ interface in a CdSe—TiO₂:N sample. All the energy levels are referenced to NHE scale. CB and VB are conduction band and valence band. Green lines and blue lines represent the energy levels of Vₒ and Nₒ respectively. The horizontal dashed line indicates H₂O/H₂ potential level. Red arrows highlight the hole and electron transfer from CdSe to TiO₂. Black dashed arrows highlight the possible electronic transitions between the different energy levels in TiO₂. The schematic diagram shows three possible competing pathways for the photogenerated holes in CdSe: (i) oxidization of S²⁻ to S₂²⁻; (ii) recombination with electrons in the conduction band, and (iii) transfer to Vₒ levels in TiO₂.

FIG. 16. Measured IPCE spectra of TiO₂, TiO₂:N, CdSe—TiO₂ and CdSe—TiO₂:N nanoparticle films in the region of 350 to 600 nm at a potential of 0 V vs. Ag/AgCl.

FIG. 17. Linear sweep voltammograms collected at a scan rate of 10 mV/s from TiO₂, TiO₂:N, CdSe—TiO₂ and CdSe—TiO₂:N nanowire arrays, in dark and with light illumination of 100 mW/cm².

FIG. 18. A general illustration of nanocrystalline TiO₂ doped with nitrogen deposited on an indium tin oxide (ITO) or fluorine tin oxide (FTO) conducting substrate. CdSe QD sensitization occurs via a linking molecule such as thioglycolic acid (TGA). Sunlight illustrated by the lightning bolts excites both the CdSe QDs as well as the TiO₂:N. Phtotogenerated electrons from CdSe are then injected into the TiO₂:N thin film and diffused to the backcontact as photocurrent.

### DETAILED DESCRIPTION OF THE INVENTION

In this disclosure, we demonstrate a relatively simple approach to dope TiO₂ nanoparticles with nitrogen and also efficiently sensitize the doped nanoparticles with CdSe quantum dots (QDs). The nanoparticle films have been characterized in terms of their structural, optical and morphological properties using a combination of experimental techniques. The results showed substantially enhanced photoresponse and high-energy conversion efficiency of the TiO₂ nanoparticle films when nitrogen doping and QD sensitization are used in unison. Possible explanations are provided in terms of the morphological and optical properties of the films. This method based on combined doping and QD sensitization is promising for solid-state PV cells and photoelectrochemical applications.

We also disclose the synthesis and photoelectrochemical (PEC) studies of TiO₂ nanoparticles and nanowires simultaneously doped with nitrogen and sensitized with CdSe quantum dots (QDs). These novel nanocomposite structures have been applied successfully as photoanodes for PEC hydrogen generation using Na₂S and Na₂SO₃ as sacrificial reagents. We observed significant enhanced photoresponse in these nanocomposites compared to N-doped TiO₂ or CdSe QD sensitized TiO₂. The enhancement is attributed to the synergistic effect of CdSe sensitization and N-doping that facilitate hole transfer/transport from CdSe to TiO₂ through oxygen vacancy states (Vₒ) mediated by N-doping. The results demonstrate the importance of designing and manipulating the energy band alignment in composite nanomaterials for fundamentally improving charge separation and transport and thereby PEC properties.

The simultaneous application of nitrogen incorporation into nanocrystalline TiO₂ thin films along with CdSe quantum dot (QD/ nanoparticle) has shown to enhance photovoltaic performance and can be utilized also for photoelectrochemical (PEC) water splitting. While nitrogen doping of TiO₂ has been performed, and shown to increase visible light harvesting, it has never been used in conjunction with CdSe QD sensitization. The two-fold advantage of this system is that (1) nitrogen doping extends the absorption of TiO₂ to 600 nm into the visible range (without doping it is 380 nm) and (2) the CdSe QDs can be exploited to further collect light depending on the size of the nanocrystals into the TiO₂:N nanocrystalline thin film. A general illustration is given in FIG. 19.

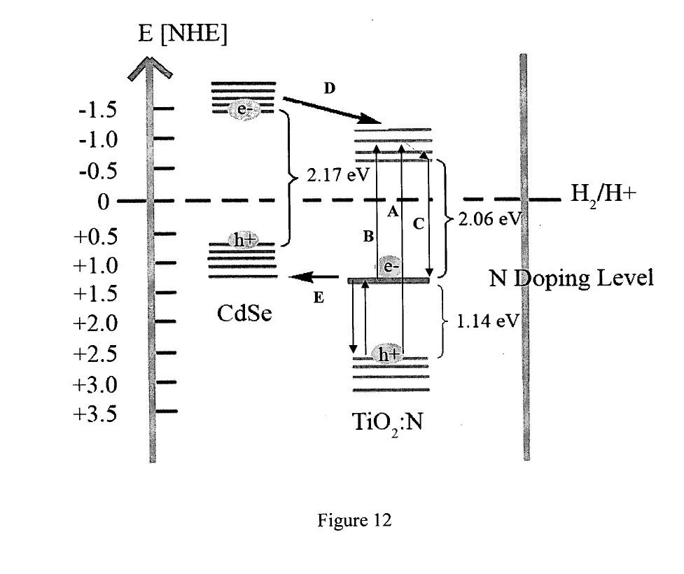

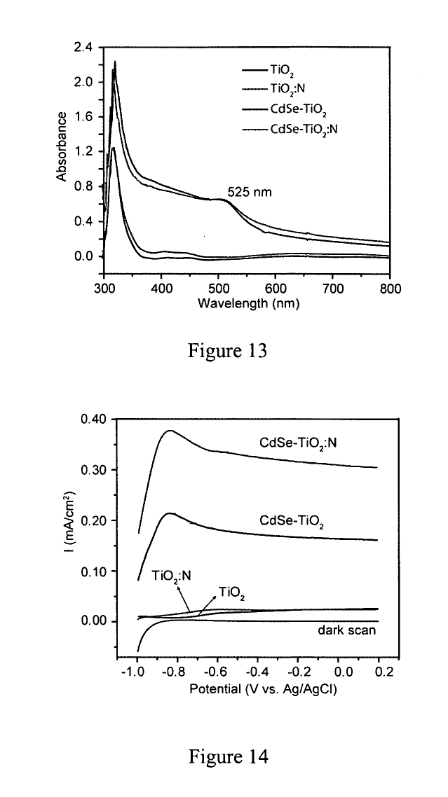

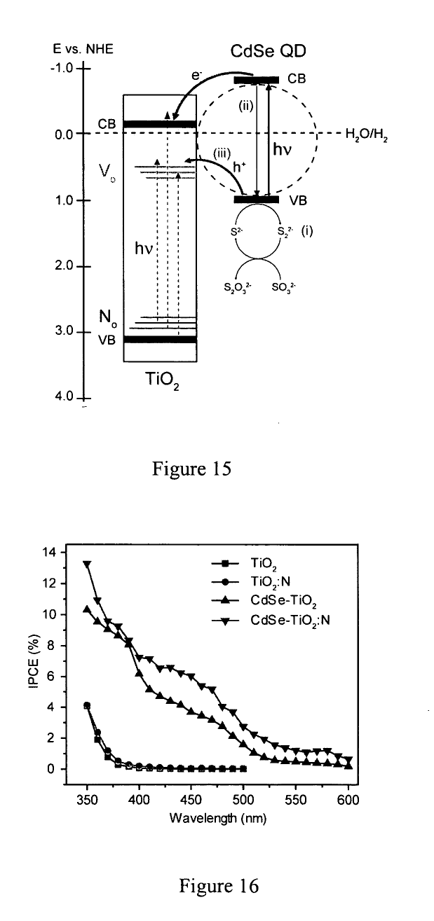

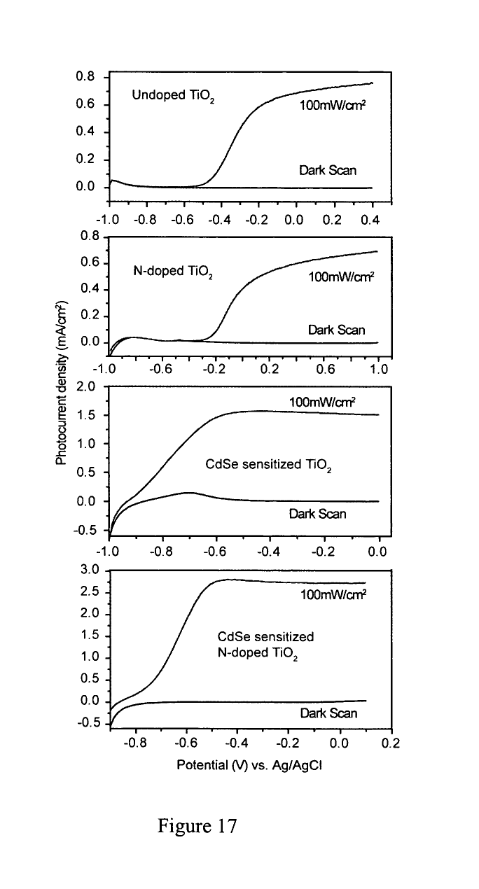

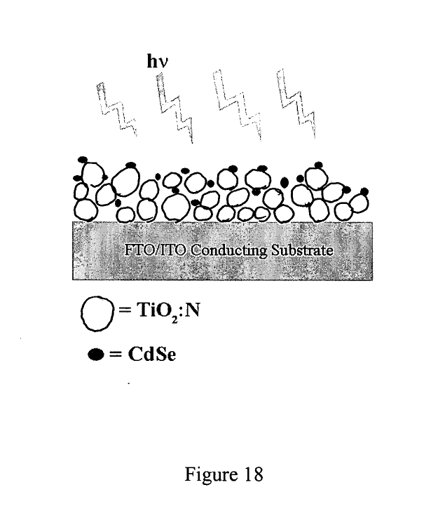

When considering the band structure of the nanocrystalline TiO₂:N in unison with the CdSe QDs, is where the unique aspects of this system arise. While it is well known that various dyes and QDs can inject electrons into the conduction band of nanocrystalline TiO₂ (Graetzel et al. supra), what is new in our system is the added benefit of the mid bandgap position of the nitrogen energy level (see FIG. 12). One embodiment encompasses the energy bands associated with a 3.5 nm CdSe QD with a bandgap of 2.17 eV. Once photoexcited by a photon of greater energy than the bandgap, an electron-hole pair or exciton is generated. The electron now being in the conduction band of CdSe is then injected into the conduction band of TiO₂:N (D) and the positive hole localized to the valence band. Photoexcited electrons in the conduction band of TiO₂:N then diffuse through the network of interconnected nanoparticles to generate a photocurrent. Other processes of photoexcitation and relaxation include arrows (A, B and C), which include excitation from the valence to conduction band of TiO₂:N (A), excitation from the nitrogen dopant energy level (B), and nonradiative recombination from the conduction band to nitrogen dopant level (C). Ultimately the most unique aspect of the doped and sensitized system is the ability for dopant level electrons from nitrogen to combine with valence band photogenerated holes. In most photovoltaic applications, hole mobility becomes the limiting factor for power conversion efficiency. The probablility of this pathway increases due to the localization of nitrogen doping on the surface of TiO₂:N and the conjugation of CdSe QDs through the TGA molecule.

Overall the performance of nitrogen doping of TiO₂ with sensitization of CdSe showed increased performance over simple CdSe sensitization of undoped TiO₂. Several types of TiO₂ thin films were produced with CdSe sensitization and during colloidal synthesis of the TiO₂, nitric acid was either not used or was used to acidify the solution to a pH=1.23. TiO₂ thin films without and with nitric acid addition achieved power conversion efficiencies of 0.120% and 0.729%, respectively, when utilized with CdSe QD sensitization. Comparatively, when hexamethylenetetramine (HMT) was used as the nitrogen dopant source in conjunction with nitric acid addition and CdSe QD sensitization we were able to achieve a power conversion efficiency of 0.840%, an increase of over 15% what was seen without nitrogen doping. We believe this is due in large part to the electron recombination discussed above along with increased light absorption of the TiO₂:N in the visible region. While success has been definitively seen with the combination of both nitrogen doping and QD sensitization, we believe it can also be successfully applied to PEC cells as well for water splitting.

TiO₂ and TiO₂:N have both been shown to be able to split water and oxidize species on their surface photoelectrochemically. Our goal is to also extend this regime of work to include the two prong doping/sensitization protocol to produce hydrogen through photolysis. With increased photocurrents in the dual TiO₂:N—CdSe system we feel the water splitting to be a natural progression from the characterization already performed in aqueous Na₂S solutions for photovoltaic applications.

### 1) Nitrogen Doped and CdSe Quantum Dot Sensitized Nanocrystalline TiO₂ Films for Solar Energy Conversion Applications

### N-Doping of TiO₂ Nanoparticles With Hexamethylenetetramine

It is known (Yin, S.; Komatsu, M.; Zhang, Q. W.; Saito, F.; Sato, T. J. Mater. Science 2007, 42, 2399) that hexamethylenetetramine_HMT) hydrolyzes in aqueous solutions to form ammonia and formaldehyde above 70° C., as shown in the following equation:

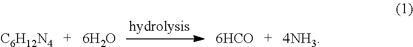

Ammonia reacts with Ti(OCH(CH₃)₂)₄ (TTIP) to form a nitrogen containing precursor (TiO₂₋ₓN_{y}.H₂O). Dehydration of the TiO₂ complex in pure and doped TiO₂ samples is completed at temperatures below 200° C. and NH₃ molecules remain until the calcination temperature rises to 300° C. Therefore, crystallization of TiO₂-ₓN_{y} can be summarized as

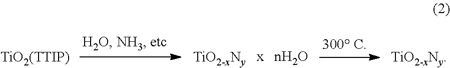

A yellowish tint was observed in all films synthesized with HMT or HMT plus PEG, suggesting the presence of a TiO₂:N sol-gel solution (Livraghi et al. supra). The XPS spectra for all the films showed two evident peaks corresponding to Ti 2p, O 1 s at 458.5 and 531.5 eV binding energies accompanying with traces of Sn from conductive SnO₂:F film over which the TiO₂ films were formed. Also traces of carbon at 284 eV were also present due to the intentional hydrocarbon contamination used for calibration. Carbon (C 1s) atoms percentage increases from 29% for TiO₂-1 to 37% and 40% for TiO₂-3 and TiO₂-4 respectively. The TiO₂-4 prepared with both HMT and PEG contains the highest carbon content, which may be attributed to uncombusted material from the precursor solutions, including HMT and PEG. The sample prepared with PEG, TiO₂-4, contains the highest carbon content. Sample TiO₂-2 prepared with nitric acid and without HMT in vacuum present extremely weak nitrogen signals at 401.2. However TiO₂-3 and TiO₂-4 films exhibit N is at ˜400 eV and 401.2 eV, which are indicative of nitrogen incorporation. We attribute N 1s at 400 eV to N atoms from N—N, N—H, O—N or N-containing organic compounds absorbed on the surface. It has been reported that N 1s features appearing above 400 eV is due to Ti—O—N linkage suggesting that doping within the crystal lattice is in fact interstitial in nature (Moribe et al. supra).

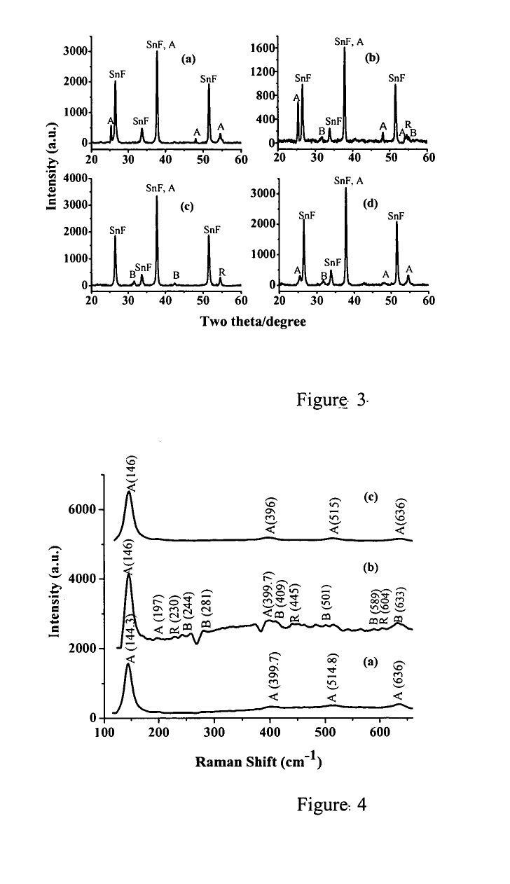

Based on the XRD patterns of different TiO₂ films (FIG. 3), nitric acid, HMT and PEG seem to have a significant effect on the TiO₂ crystalline structure. The phase composition appears to be strongly related to the added quantity of nitric acid, and therefore to pH. The film prepared without nitric acid shows pure anatase structure (FIG. 3a). A reduction of the pH to 1.23 resulted in the appearance of rutile and brookite phases mixed with anatase (FIG. 3b). However, for the samples prepared with HMT at pH˜1.65, the antase phase decreases (FIG. 3c). These results suggest that nitric acid and HMT promote the formation of brookite and rutile phases. The reason for this is not yet clear and needs further study. When added, PEG increases the pH to ˜2.06, and the corresponding film shows a presence of the brookite and rutile phases (FIG. 3d). Further research is also needed to understand the possible correlation between the different crystal phases and their photovoltaic performance.

The phases determined by XRD are supported by Raman scattering spectroscopy measurements of the films (FIG. 4). The TiO₂-1 thin film shows Raman peaks at 144, 399, 515 and 636 cm⁻¹ (FIG. 4a), which indicate a pure anatase crystal phase based on a previous report (Djaoued et al.). TiO₂-3 thin film shows vibrational modes at about 244, 281, 409, 501, 589, and 633 cm⁻¹, indicative of the brookite phase, and peaks at 230, 445, and 604 cm⁻¹, indicative of a rutile phase. The TiO₂-2 films contains a mixture of peaks that can be attributed to anatase, brookite, and rutile phases, as a result of nitric acid incorporation. The lowest frequency mode shifts slightly for these films to 146 cm⁻¹ as compared to 144 cm⁻¹ for the pure anatase (TiO₂-1). This might be caused by changes in crystallographic composition due to nitrogen doping attributed to the vibrations of Ti—N—O introduced by nitric acid and HMT. Raman spectrum of the TiO₂-4 thin film shows that PEG suppresses the formation of the rutile and brookite phases, also consistent with XRD data. The intensity of the 146 cm⁻¹ peak for the TiO₂-3 film is higher and sharper than undoped TiO₂, indicating good crystallinity and size uniformity of the TiO₂:N film.

### Morphologic Properties

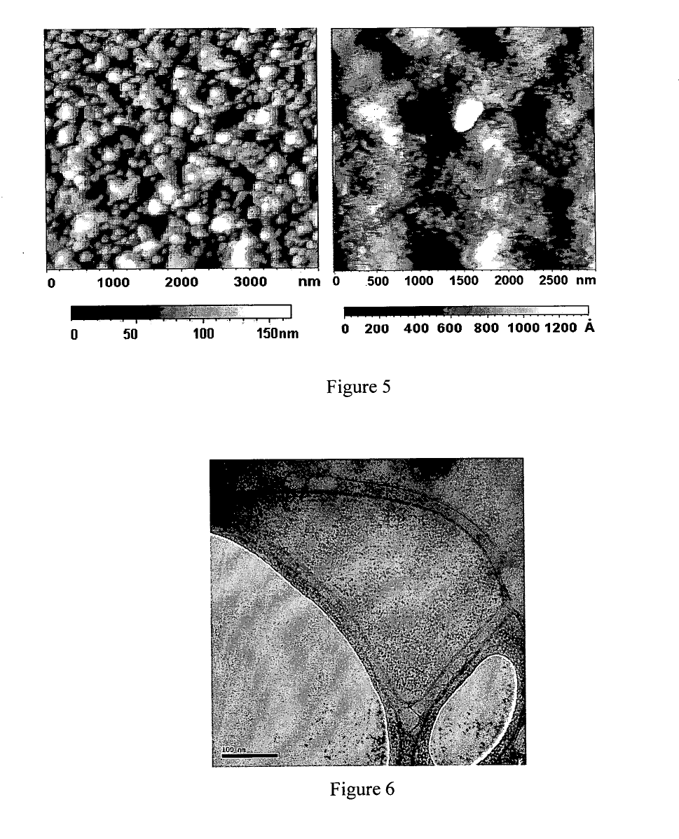

Composition of the thin films was observed to be a mix of individual particles interconnected with high porosity. However, TiO₂-3 and TiO₂-4 films were far more porous than TiO₂-1 and TiO₂-2 films. This suggests that HMT and PEG promote porosity as was previously demonstrated in the case of PEG interacting with TiO₂ systems (Liu, X. X.; Jin, Z. G.; Bu, S. J.; Yin, T. J. Sol-Gel Sci. Techn. 2005, 36, 103). The morphology was noticeably more evident by AFM due to an atomically flatter surface produced with thin films on the order of 150 nm in thickness. The surface properties of the TiO₂:N films are expected to be important in determining how well the CdSe QDs can link to and interact with the TiO₂ nanoparticles. AFM images of all TiO₂ films functionalized with CdSe QDs clearly show the presence of QDs as evidenced by the apparent flattening of the films in the AFM images (for example, FIG. 5 for the TiO₂-3-TGA-CdSe film).

### Optical Properties

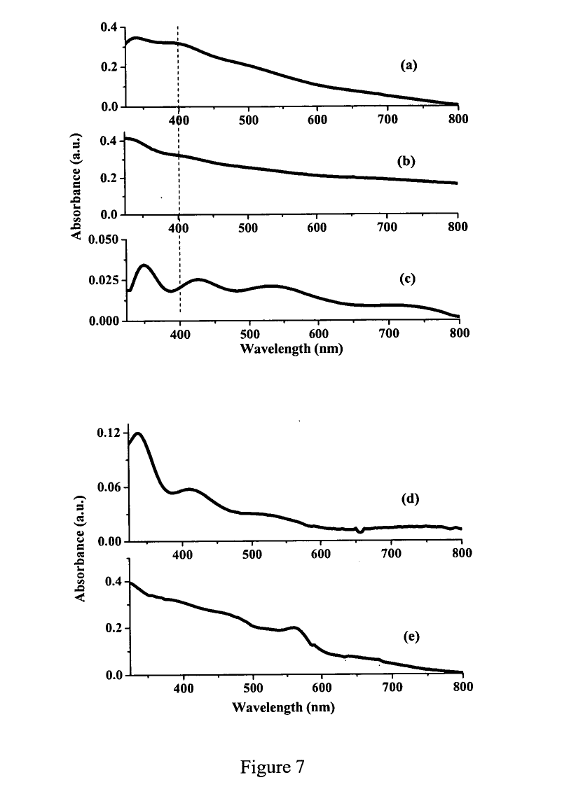

Comparison of the absorption spectra of all samples under study show that films without HMT and PEG (TiO₂-1 and TiO₂-2) have absorption around 340 and 400 nm respectively. However, TiO₂-3 and TiO₂-4 films with HMT or HMT plus PEG have a red shift of the absorption edge toward the visible region at 600 nm for samples annealed at 550° C. due to the electronic transition of N 2p_{π} to Ti d_{xy} (FIGS. 7c and 7d). The red-shift absorption can be attributed to the doping of nitrogen into the crystal lattice of TiO₂ due to the addition of HMT in the sol gel solutions. TiO₂-3 and TiO₂-4 films and calcined powders are also yellowish in color, attributed to the presence of nitrogen that results in the effective narrowing of the bandgap. All the films sensitized with CdSe QDs exhibit strong absorption at 560 nm, which is the characteristic excitonic absorption band of CdSe QDs (FIG. 7e).

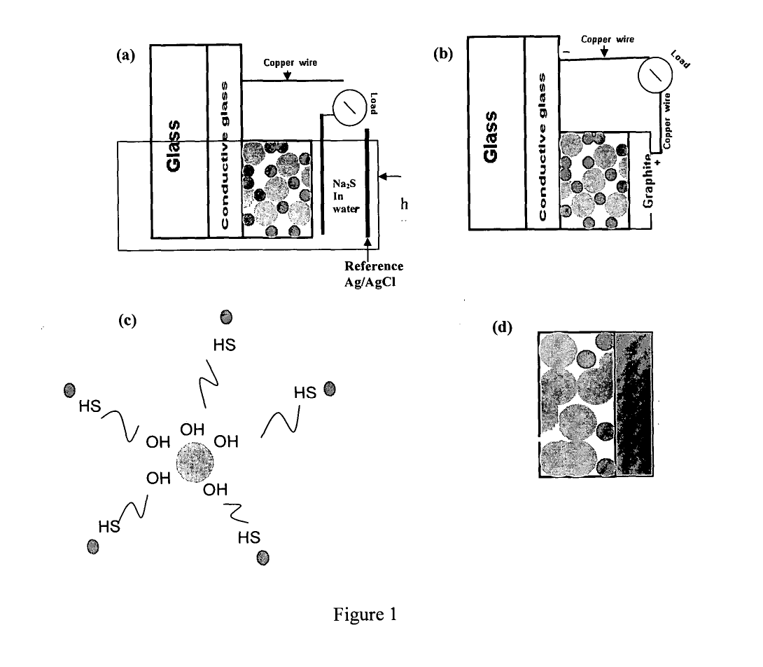

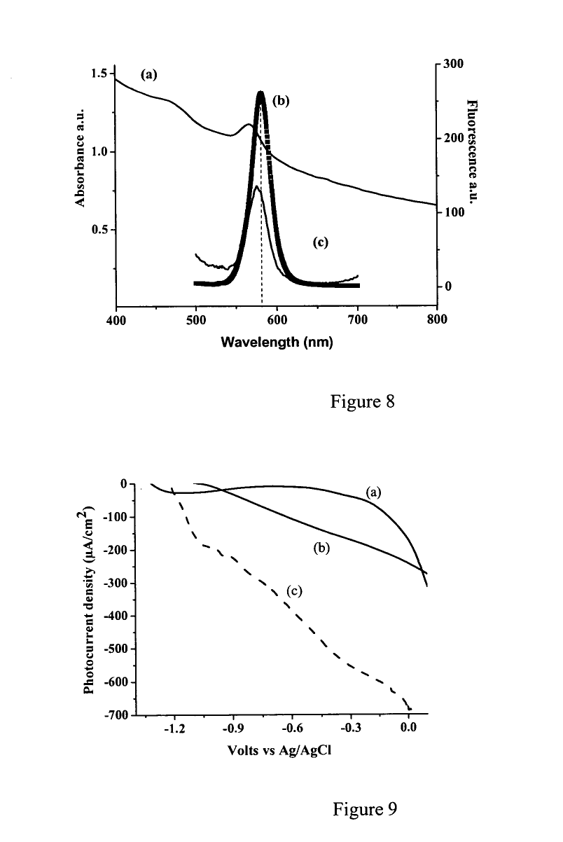

As shown in FIG. 8, CdSe QDs in solution exhibit strong and narrow bandedge emission at 580 nm while the PL spectrum of the TiO₂-3-TGA-CdSe film shows a weak and blue-shifted PL band peaked at 575.5 nm. These results suggest interactions between TiO₂ nanoparticles and CdSe QDs and likely electron injection from CdSe to TiO₂. The small blue-shift of the PL peak could be due to slight oxidation of the film exposed to the atmosphere and thus a decrease in CdSe QD size during the sensitization process. The electron transfer process indicated by PL quenching is supported by photoelectrochemical measurements to be discussed later. TiO₂-1 and TiO₂-2 films also have emissions in 580 nm due to CdSe QDs. However, there is no blue-shift of the PL spectrum. This is possibly because the TiO₂-1-CdSe and TiO₂-2-CdSe have lower porosity than TiO₂-3 and TiO₂-4 and the CdSe QDs are not inside the pores of the TiO₂ film and thereby have weak interactions with TiO₂ nanoparticles. This is illustrated schematically in FIG. 1d. The average QD size is estimated to be 3.5 nm based on the absorption spectrum.

### Photoelectrochemical and Photovoltaic Characterization

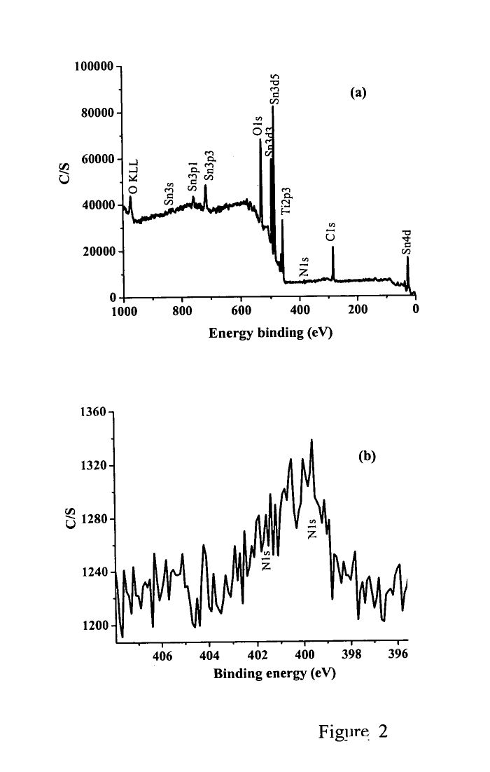

As summarized in Table 1, thin and thick films sensitized with CdSe QDs show enhanced photocurrents and power conversion efficiency under white light, in comparison to films without sensitization of CdSe QDs. The greatest enhancement was observed for TiO₂ films doped with nitrogen and simultaneously sensitized with CdSe QDs. What is interesting is that the QD-sensitized TiO₂:N shows much larger enhancement than the simple sum of just N-doping and only QD sensitization, especially in terms of photocurrents (FIG. 9). One possible explanation is that N-doping alters the surface property of the TiO₂ film so that the interaction between TiO₂ and CdSe QDs becomes stronger and allows for more efficient electron injection. XPS data also revealed a localization of nitrogen upon the surface (FIG. 2b), and binding between exposed Cd²⁺ and surface nitrogen atoms on TiO₂ could also increase interaction The porosity of the TiO₂ film could also be affected by N-doping that in turn influences how the CdSe QDs enter the pores and adsorb on to the TiO₂:N nanocrystalline surface. The mixed brokite and rutile phases could also have some effect on the CdSe—TiO₂ interaction.

TABLE 1
Summary of the fill factor and power conversion efficiency results from
our study of N—TiO₂-TGA-CdSe based solar cell in electrolyte (Na₂S).
The power light was 27 mW/cm² (¼ of AM1.5) equivalent irradiance.

| | | | | | |
|---|---|---|---|---|---|
| | | −V_{oc}, | | | Power |
| | −I_{sc} | (V vs | (JV)ₘₐₓ | Fill | Conversion |
| | (μA/ | Ag/ | (μA/ | Factor | Efficiency |
| Cell | cm²)., | AgCl | cm² * V) | (FF %) | (η %) |

Thin films

| | | | | | |
|---|---|---|---|---|---|
| TiO₂-1 | 19 | 0.5 | 9.5 | 14.1 | 4.96 × 10⁻³ |
| TiO₂-3 | 19 | 0.7 | 13.3 | 14.5 | 7.14 × 10⁻³ |
| TiO₂-4 | 19 | 0.74 | 14.1 | 11.3 | 5.88 × 10⁻³ |
| TiO₂-3-TGA-CdSe | 242 | 1.0 | 242 | 25.4 | 2.28 × 10⁻¹ |

Thick films

| | | | | | |
|---|---|---|---|---|---|
| TiO₂-1 | 25 | 0.5 | 12.5 | 24 | 1.11 × 10⁻² |
| TiO₂-1-TGA-CdSe | 169 | 1.3 | 219.7 | 14.8 | 1.20 × 10⁻¹ |
| TiO₂-2-TGA-CdSe | 400 | 1.2 | 480 | 41 | 7.29 × 10⁻¹ |
| TiO₂-3-TGA-CdSe | 683 | 1.2 | 819 | 27.7 | 8.40 × 10⁻¹ |
| TiO₂-4-TGA-CdSe | 390 | 0.62 | 241 | 10.37 | 9.25 × 10⁻² |

For the thick TiO₂-1 and TiO₂-2 films, it was also observed that a layer of CdSe QD film formed on the TiO₂ film surface. This seems to indicate that CdSe QDs did not all disperse into the pores of the TiO₂ films efficiently, and were instead localized upon the TiO₂ surface. Therefore, CdSe QDs inject electrons mainly in the TiO₂ film surface, with CdSe QDs in contact with a thin layer of TiO₂ nanoparticles, which could possibly explain why the short circuit current, FF, and conversion efficiency are low for these two films. However, the conversion efficiency of TiO₂-2 is higher than that of TiO₂-1, probably due to nitrogen residues from the nitric acid added to TiO₂ sol.

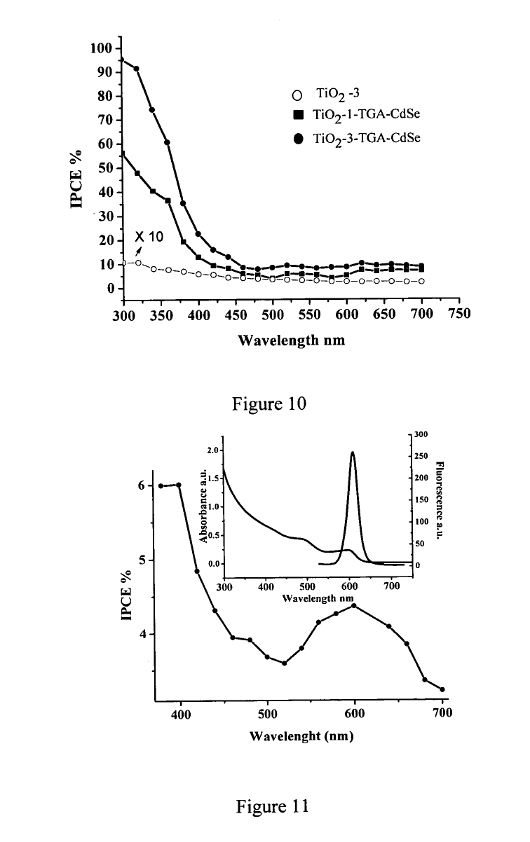

In comparison to the thick TiO₂-3-TGA-CdSe film with the highest power conversion efficiency (η=0.84%), the TiO₂-4-TGA-CdSe (CdSe QD sensitized with HMT and PEG) has lower conversion efficiency. This could possibly be due to a weakened interaction between CdSe QDs and TiO₂ nanoparticles caused by hydrocarbon species on the TiO₂ surface from uncombusted polyethylene glycol (PEG). It is clear that IPCE is enhanced when the films were sensitized with CdSe QDs (Table 2) due to their strong visible absorption and electron injection. The highest IPCE percentage was found for TiO₂-3-TGA-CdSe films (95% in 300 nm) where the larger content of brookite and rutile phases of the TiO₂:N was present. The lower IPCE in TiO₂-1 samples is possibly due to the lower porosity and probably due to the presence of the anatase crystalline phase (FIG. 10). The performance of the solid solar cell is similar to that reported previously, as shown in FIG. 11 (Grant, C. D.; Schwartzberg, A. M.; Smestad, G. P.; Kowalik, J.; Tolbert, L. M.; Zhang, J. Z. J. Electroanal. Chem. 2002, 522, 40). In this case, the highest IPCE is 6% at 400 nm and a strong response, larger than 4%, was observed at 600 nm. The first increase at 600 nm is attributed to the absorption onset of the 4.6 nm QDs utilized to sensitize the TiO₂-3-TGA-CdSe film. The direct overlap with the first excitonic band (inset FIG. 11) of the CdSe QDs with the IPCE measurements confirms the electron injection into the TiO₂ conductive band. This in turn, confirms the important role of the QDs to harvest photons and increase the generated photocurrent. All these results indicate the sensitive dependence of the cell performance on the film porosity, QD-TiO₂ interaction, and N-doping.

The electronic band structure of CdSe QD and TiO₂:N could help to better understand the reason behind increased performance in TiO₂:N thin films sensitized with CdSe. FIG. 12 shows different electron-hole relaxation, recombination pathways and band structure of both CdSe QDs with a bandgap of 2.17 eV (3.5 nm in average diameter) and nitrogen doped TiO₂ with an overall bandgap of 3.2 eV at pH=7. The band diagram of CdSe and TiO₂:N have both been placed in relation to the normal hydrogen electrode (NHE). CdSe QDs of 3.5 nm has a top valence band position of ca. +0.7 V and a lower conduction band of ca. −1.4 V based on previous reports (Robel, I.; Subramanian, V.; Kuno, M.; Kamat, P. V. J. Am. Chem. Soc. 2006, 128, 2385). The band structure of TiO₂:N in turn has a valence band at ca. +2.6 V and a conductive band at ca. −0.6 V based on the work by Sakthivel and Kisch (Sakthivel, S.; Janczarek, M.; Kisch, H. J. Phys. Chem. B 2004, 108, 19384; Sakthivel, S.; Kisch, H. Chemphyschem 2003, 4, 487). N doping introduces a state at 1.14 eV above the valence band and 2.06 eV (600 nm absorption onset) below the conduction band of TiO₂ (Di Valentin et al. supra). Several groups have also reported an absorption onset at 600 nm via reflectance spectroscopy Chen, X. B.; Burda, C. J. Phys. Chem. B 2004, 108, 15446; (Burda, C.; Lou, Y. B.; Chen, X. B.; Samia, A. C. S.; Stout, J.; Gole, J. L. Nano Letters 2003, 3, 1049; and Gole, J. L.; Stout, J. D.; and Burda, C.; Lou, Y. B.; Chen, X. B. J. Phys. Chem. B 2004, 108, 1230). Incorporation of nitrogen into nanocrystalline TiO₂ acts as an electron acceptor site within the TiO₂ bandgap, and effectively should be considered a p-type doping. This state acts as an electron acceptor site within the TiO₂ bandgap. Now it is still important to consider the typical n-type behavior of TiO₂ as a result of oxygen vacancies in the crystal lattice, and therefore act as donor sites within the structure, and effectively increase the Fermi level (E_{f}) to more negative potentials (versus NHE). The bandgap dopant N state is populated as evidenced by the weak absorption onset at 600 nm (2.06 eV) explained by Asahi et al. (2001, supra) as a N 2p_{π} to Ti d_{xy}, transition. Due to the relatively weak absorption of this N 2p_{π} to Ti d_{xy} electronic transition in comparison to the quantum confined CdSe transition (1Sₕ1Sₑ) transition, we expect that, for the CdSe QD sensitized TiO₂:N films, the optical absorption is dominated by the CdSe QDs.

To understand the charge transfer and recombination kinetics, we will ignore the weak absorption due to N-doping for the QD sensitized TiO₂:N film. In this case, photoexcitation of the CdSe QD generates a hole in its valence band and an electron in its conduction band. The electron in the conduction band of CdSe QD is injected into the conduction band of TiO₂ (left to right yellow arrow) and the transfer of the hole in the valence band of CdSe can be mediated by the electron occupied N state (right to left yellow arrow). The energy level of the N state is close to the top of the valence band of CdSe and this proximity in energy will aid in the hole (or electron) transfer process. Since this only exists for the CdSe QD sensitized and N-doped TiO₂ film, the N-mediated hole transport may be the key to the enhanced photoelectrical response of this film compared to TiO₂ films with only N doping or only QD sensitization. This is possible, especially considering that the hole transport is often the limiting step for overall charge transport in nanoparticle films.

It is clear that N doping into TiO₂ has introduced extra pathways for the charge carriers that could be beneficial for overall chare transport and thereby cell performance. Optimization of the system via an increased dopant level (currently 0.6-0.8%, see Table 1) and manipulation of the capping agents of CdSe may further enhance the photocurrent density as well as power conversion efficiency above that of 0.84% currently observed.

### Conclusions

Several TiO₂ films with nitrogen doping and/or CdSe QD sensitization have been systematically investigated using a combination of synthetic, spectroscopic, XRD, XPS, microscopy, and electrochemistry techniques. The structure of TiO₂:N has been found to be generally a mixture of anatase, brookite, and rutile phases. Nitrogen doping into the TiO₂ lattice results in a red-shift of the electronic absorption and enhanced photocurrent response of relative to undoped TiO₂ films. In addition, CdSe QDs linked to TiO₂:N nanoparticles were found to significantly increase the photocurrent and power conversion of the films compared to standard TiO₂:N films without QD sensitization. The IPCE is 6% at 400 nm for TiO₂:N-TGA-CdSe solid state solar cells and 95% for TiO₂:N-TGA-CdSe films near 300 nm in a Na₂S electrolyte, which is much higher than undoped TiO₂ with QD sensitization or TiO₂:N without QD sensitization. A power conversion efficiency (ᵢ) of 0.84% was found along with a fill factor (FF %) of 27.7% for 1100 nm thick TiO₂:N-TGA-CdSe thin films. The results show that the combination of nitrogen doping and QD sensitization of TiO₂ thin films is an effective way to enhance the photoresponse, which is promising for photovoltaic (PV) and photoelectrochemical applications.

One exemplary application comprises a photovoltaic cell comprising the thin film structure as disclosed herein. In one embodiment, the photovoltaic cell has a power conversion efficiency of between 1·10 and 5 η %. In another embodiment the power conversion efficiency is of between 5·10 and η %. For example, the power conversion efficiency can be 1·10⁻³, 2.5·10⁻³, 5·10⁻³, 1·10⁻², 2.5·10⁻², 5·10⁻², 1·10⁻¹, 2.5·10⁻¹, 5·10⁻¹, 1, 1.5, 2, 2.5, 3, 3.5, 4, 4.5, and 5 η %.

In another embodiment the photovoltaic cell has an incident photon to current conversion efficiency (IPCE) of between 1% and 99%. In another embodiment, the IPCE is of between 13% and 95%. In another embodiment the IPCE is of between 25% and 90%. In yet another embodiment the IPCE is of between 50% and 85%. For example, the IPCE can be 1%, 2%, 5%, 7.5%, 10%, 12.5%, 15%, 17.5%, 20%, 25%, 30%, 35%, 40%, 45%, 50%, 55%, 60%, 65%, 70%, 75%, 80%, 85%, 90%, 95%, 96%, 97%, 98%, 99%, and 99.5%.

### 2) Synergistic Effect of CdSe Quantum Dot Sensitization and Nitrogen Doping of TiO₂ Nanostructures for Photoelectrochemical Applications

Our lab has demonstrated a synergistic effect in combining CdSe QD sensitization with N-doping of TiO₂ that substantially increases photovoltaic response and was tentatively attributed to increased hole transport from the CdSe valence band to the N dopant level (Lopez-Luke et al. supra). In this work, we report the first example of CdSe QD sensitized and N-doped TiO₂ nanomaterials for PEC hydrogen generation with substantially enhanced photocurrent. Again, significant synergistic effect between QD sensitization and N-doping has been observed. A detailed study reveals that it is still the enhanced hole transfer/transport that is responsible for the observed synergistic effect, however, the enhanced hoe transfer/transport is not directly coupled to the N energy levels but is rather caused by oxygen vacancy states (Vₒ) of TiO₂ that is mediated indirectly by N-doping.

We have synthesized novel nanocomposite materials based on visible light-absorbing CdSe QDs and N-doped TiO₂ nanoparticles and nanowire arrays with properties tailored for PEC hydrogen generation. We have experimentally demonstrated for the first time, to our best knowledge, that the synergistic effect of sensitization and elemental doping significantly enhances the photoelectrochemical activities of the TiO₂ nanostructured photoanodes. These composite nanostructures show enhanced overall charge transport and improved PEC performance when the relevant bandgap states are properly aligned and utilized. Enhanced electron-hole separation and hole transfer/transport through the oxygen vacancy states, Vₒ, mediated by N-doping has been proposed to explain the observed experimental results. Such nanocomposite structures simultaneously enhance visible light absorption and interfacial charge transfer. The results provide useful insights for developing new nanostructures tailored for PEC and other applications via controlled band engineering.

The invention will be more readily understood by reference to the following examples, which are included merely for purposes of illustration of certain aspects and embodiments of the present invention and not as limitations.

### EXAMPLES

### Example I

### Experimental Sample Preparation

### A. Materials.

Titanium(IV) iso-propoxide (#377996, 99%), technical grade trioctylphosphine (TOP-#117854, 90%), trioctylphosphine oxide (TOPO #223301, 99%) , potassium chloride (KCl-#204099 , 99%), polyethylene glycol (PEG-#25322-68-3, average Mₙ ca. 10,000 g/mol) and sodium sulfide (Na₂S-#407410, 99%) were obtained from Sigma-Aldrich (Milwaukee, Wis.). Cadmium oxide (CdO-#223791000, 99%) and selenium powder (Se 200 mesh-#198070500, 99%) were obtained from Acros organics (Morris Plains, N.J.). 1-tetradecylphosphonic acid (TDPA-#4671-75-4, 99%) was obtained from PCI synthesis (Newburyport, Mass.). Nitric acid (2.0N-#LC178502) was purchased from Lab. Chem Inc (Pittsburgh, Pa.). Thioglycolic acid (TGA-#103036, 98%) was obtained from MP Biomedicals Inc.(Solon, Ohio). F:SnO₂ conductive glass (Tec glass 30 Ohms) was obtained from Hartford glass (Hartford City, Ind.) and the reference electrodes Ag/AgCl from CH Instruments Inc. (Austin, Tex.).

### B. TiO₂ Film Preparation.

Four kinds of TiO₂ films (TiO₂-1, TiO₂-2, TiO₂-3 and TiO₂-4) were made by a sol-gel method. All TiO₂ films were made using 375 μL of titanium iso-propoxide as a precursor which was stored in a nitrogen filled glovebox. For TiO₂-1, TiO₂-2, TiO₂-3 and TiO₂-4, titanium iso-propoxide was injected into 250 μl of Milli-Q water and 5 mL of ethanol within the glovebox. TiO₂-1 solutions did not contain nitric acid, while TiO₂-2 solutions contained a drop wise addition of nitric acid until the solution reached a pH 1.23. TiO₂-3 solutions is similar to TiO₂-2, but 0.05 g of HMT was added under vigorous stirring. Solution TiO₂-4 is similar to TiO₂-3 with an addition of 0.90 g of polyethyleneglycol (PEG-10,000 g/mol) under vigorous stirring all within an O₂ free environment. As a point of clarification, acidification (TiO₂-2, TiO₂-3 and TiO₂-4) was performed outside of the glovebox prior to titanium isopropoxide addition within the glovebox. The sol was then stirred for three days within the glovebox at ambient temperatures (·25° C.). All TiO₂ films were made by spin coating at 2000 rpm for 60 seconds onto FTO (SnO₂:F) conducting substrates in ambient conditions. The thickness was estimated with mass, area and density of the TiO₂ films and was confirmed with AFM measurements (˜150 nm and ˜1100 nm thick). The films were annealed at 550° C. for 1.5 hours with a Leister heat gun in open air conditions. For thin TiO₂-1, TiO₂-2, TiO₂-3 and TiO₂-4 films, 50, 200, 100 and 50 μL of the sol solution was used, respectively. For thick TiO₂-1, TiO₂-2, TiO₂-3 and TiO₂-4 films, 400, 2000, 700, 250 μL respectively of the sol solution was used. The sol solution was put on the conductive glass with 1×2.2 cm² areas, respectively. It was necessary to apply different volumes in order to obtain approximately the same film thickness because of the different viscosities of the various solutions.

### C. CdSe QD Synthesis.

High-quality CdSe QDs were synthesized based upon the protocol of Qu, Peng, and Peng (2001) wherein CdO is utilized as the Cd precursor, and TDPA and TOPO are the ligands and coordinating solvents, respectively (see Qu, Peng, and Peng, Nano Letters 2001, 1, 333). The resulting CdSe nanocrystals were in the strong confinement size regime and were synthesized in normal air-free reaction conditions. The synthesis of the CdSe nanoparticle follows the procedure reported by Robel et al. wherein 0.05 g (˜0.39 mmol) CdO, 0.3 g (˜1.1 mmol) TDPA and 4 g of TOPO was heated to 110° C. and degassed under vacuum and then heated to 300° C. under a nitrogen flow (Schlenk line) (Robel et al. Am. Chem. Soc. 2006, 128, 2385). A SeTOP (0.7% by weight) solution was obtained by adding 0.026 g of Se powder with 4.25m1 of TOP inside a glove box and stirred for 1 hr to insure complete dissolution of the Se powder. After reaching 300° C. the Cd-TDPA-TOPO solution was cooled to 270° C. prior to the injection of SeTOP. Under a nitrogen flow, 3 ml of SeTOP was injected, which resulted in the lowering of the temperature to 260° C. The temperature was then increased to 280° C. to facilitate particle growth and aliquots were removed and probed to track nanocrystallite growth via UV-vis absorption spectroscopy and photoluminescence (PL) spectroscopy. The CdSe solution was cooled and was removed from the reaction flask at around 80° C. and dissolved into ˜10 mL of toluene. The QDs in toluene were then cleaned twice through a precipitation and decantation regime using methanol and centrifugation at 3000 rpm, and the QDs were ultimately redissolved in toluene prior to their use as a sensitizer.

D. CdSe QD linkage to TiO₂.

CdSe QDs were linked to nanocrystalline TiO₂ and TiO₂:N thin films using TGA as a molecular linker. TiO₂ has a strong affinity for the carboxylate group of the linker molecules, while the sulfur atom of TGA binds strongly to CdSe nanoparticles through surface Cd²⁺ cations. The films were heated in a heat gun at 100° C. for 4 hrs to remove H₂O from the surface due to ambient humidity adsorption. They were later immersed in undiluted neat TGA for 12 hrs in a nitrogen environment in a glove box. The films were then immersed in toluene, removing the excess TGA and in turn immersed in a CdSe solution for 12 hrs inside the glove box. Four films of 1×1 cm² were immersed in 5 ml of CdSe QDs suspended in toluene as described earlier. The TiO₂:N-TGA-CdSe films were stored in a nitrogen filled glove box and not exposed to light prior to PEC characterization. The solid state TiO₂:N-TGA-CdSe cell after PEC measurements remained stable for months. The TiO₂:N-TGA-CdSe cell in the electrolyte is very stable, however, when is removed from the electrolyte the PEC properties diminish after a hours of experimentation. Long term stability need to be further studied in future research.

### Example II

### Structural and Morphology Characterization

X-ray photoelectron spectroscopy (XPS) studies of the films were carried out on an X-ray photoelectron spectrometer (XPS, PHI Quantera SXM) using a non-monochromatized Al KR X-ray source (1486.6 eV). The energy resolution of the spectrometer was set at 0.5 eV. The binding energy was calibrated using a C 1s (284.6 eV) spectrum of a hydrocarbon that remained in the XPS analysis chamber as a contaminant. Crystalline phase identification was performed via X-ray diffraction (XRD) in conjunction with Raman spectroscopy. XRD analysis was conducted on a MINIFLEX diffractometer operating at 30 kV/15 mA using Cu—Kα radiation and scanning speed of 1° 2θ/min.

Raman spectroscopy of the films was performed using a Renishaw micro-Raman setup with a (5/ 10/ 20/ 50)× objective lens and a 633 nm excitation wavelength. Renishaw's WiRE (Windows based Raman Environment) was used for collection and data analysis of 1 to 5 scans ranging in accumulations of 1 to 10 seconds.

AFM images of the films without and with QDs were acquired under ambient conditions with a PicoLE SPM instrument (Molecular Imaging) in tapping mode: The tapping mode cantilevers exhibit resonant frequencies between 60 and 90 kHz (typical 75 kHz), force constants of 2.5-5.5 N/m, and tip apex radii of ˜10 nm. The resulting images were flattened and plane-fit using software from Molecular Imaging. Silica etched tips were purchased from MikroMasch (Watsonville, Oreg.).

A JEOL model JEM-1200EX microscope was used for the low-resolution transmission electron microscope (TEM) studies of the CdSe QDs. The TEM was equipped with a Gatan Model 792 Bioscan digital camera running on a Windows 2000 computer with Gatan Digital Micrograph as the analyzing software.

### Example III

### Optical and Electrochemical Characterization

UV-visible light (UV-vis) absorption spectroscopy was conducted on a Hewlett-Packard 8452A diode array spectrophotometer. UV-vis absorption spectra were measured first by placing a blank FTO glass substrate in the light path, subtracting the absorption pattern, and then performing the UV-VIS absorption measurement on the variety of TiO₂ thin films.

Photoluminescence (PL) spectroscopy was gathered on a Perkin Elmer LS 50B with an excitation wavelength of 390 nm and 1% attenuator. QDs in toluene were placed in an open sided 1 cm path length quartz cuvette for both UV-vis absorption and PL measurements. Thin films were placed in a thin film sample holder from Perkin Elmer (#52123130) for PL spectra.

Photoelectrochemical studies (linear sweep voltammetry and incident photon-to-current conversion efficiency (IPCE) in solid state and in electrolyte were carried out with a CHI440 electrochemical workstation (Austin, Tex). Linear sweep voltammetry was used to obtain the I-V profiles. Actively investigated thin films were the TiO₂, TiO₂:N and TiO₂:N—CdSe thin films described earlier. A Ag/AgCl and Pt wire coil were used as reference and counter electrodes, respectively. Before each measurement the Na₂S electrolyte solution was deaerated by bubbling ultra-high-purity N₂ for 20 minutes through the electrolyte solution and a nitrogen flow was also subsequently blown over the surface during data gathering. For I-V measurements a halogen lamp was utilized (75 watts) and for IPCE measurements and a 1000 W Xe lamp (Oriel Research Arc Lamp assembly #69924 and power supply #69920) coupled to a infrared (IR) water filled filter (Oriel #6127), and then aligned into a monochromator (Oriel Cornerstone 130 ⅛ m) for spectral resolution from 300 to 800 nm,. An aqueous Na₂S solution serves as the redox couple to maintain the stability of the QD's, as discussed elsewhere (Mueller, N.; Tenne, R.; Cahen, D. J. Electroanal. Chem. 1981, 130, 373; Ueno, Y.; Minoura, H.; Nishikawa, T.; Tsuiki, M. J. Electrochem. Soc. 1983, 130, 43). A maximum photocurrent was produced with 1 M Na₂S using 6.5 ml of Milli-Q water (18 MΩ). Diminished molarities of Na₂S were found to decrease overall photocurrent performance. IPCE measurements were also conducted for solid state TiO₂:N-TGA-CdSe solar cells. A schematic of the photoelectrochemical setup is shown in FIG. 1(a-b).

### Example IV

### Results

The amount of nitrogen in N-doped TiO₂ nanoparticle films was identified by the XPS technique. FIG. 2 shows the XPS spectra for the TiO₂-3 film. FIG. 2a shows the Ti2p, O1s, C1s, N1s and Sn binding energy from 0 to 1000 eV (Sn is identified from the conductive film). FIG. 2b shows only the nitrogen binding energy from 396 to 408 eV, showing two peaks at 400 and above 401.2 eV. To compare the effect of HMT and PEG, TiO₂-3 film has 37.45% of C, 0.60% of N, 50.16% of 0 and 11.79% of Ti. TiO₂-4 film shows elemental composition of C and N of 39.93% and 0.80%, respectively, with 48% of O and 11.27% of Ti.

FIG. 3 shows the XRD patterns for all the films prepared, respectively, for determining the crystal phases of both TiO₂ and TiO₂:N. All the XRD data show the crystal phase of the conductive glass (SnO₂:F), which is marked as (SnF). The TiO₂-1 film (without nitric acid) XRD pattern is representative of the anatase crystal phase (FIG. 3a). For the TiO₂-2 film (with nitric acid), the brookite and rutile phases appear, with a mix of anatase, brookite and rutile phases (FIG. 3b). With HMT added for the TiO₂-3 film, a mixture of brookite and rutile phases dominate with a trace amount of anatase phase (FIG. 3c). With further addition of PEG and HMT, as in the TiO₂-4 film, the brookite and rutile phases decrease and the anatase is predominant. Additional evidence for the various crystal phases of the different films comes from their Raman spectra that show anatase as the primary phase for TiO₂-1 and TiO₂-4, (FIGS. 4a and 4c) and a mix of anatase, brookite and rutile phases in TiO₂-2 and TiO₂-3 films. Representative Raman spectrum of the TiO₂-3 film is shown in FIG. 4b. It can be seen that the characteristic peak for the anatase phase at 144 cm⁻¹ shifts slightly to 146 cm⁻¹ with nitrogen doping (TiO₂-3 and TiO₂-4 films).

Morphology of the films with and without QDs was studied by AFM in ambient conditions. The average TiO₂ nanocrystal size was found to be around 100 nm in diameter. Films with HMT (TiO₂-3) or HMT plus PEG (TiO₂-4) show more porosity than TiO₂-1 and TiO₂-2 films. A representative AFM image for the TiO₂-3 film with about 150 nm thickness is shown in FIG. 5a. For thicker films (for example, 1100 nm), TiO₂ particles were observed to form clusters. All films show the presence of CdSe QDs after they were sensitized, as exemplified by the AFM image for the TiO₂-3-TGA-CdSe film shown in FIG. 5b. While it is not easy to determine the exact size of the CdSe QDs based on AFM, the average size of the QDs appear to be on the order of a few nanometers. To better characterize the CdSe QDs, TEM measurements was conducted. FIG. 6 shows a representative TEM image of CdSe QDs. The image appears to show reasonably uniform size distributions of the CdSe QDs with an average diameter of 3.5 nm.

Optical absorption of the different films was characterized by UV-Vis spectroscopy, with emphasis on comparing the effect of nitrogen doping through HMT or nitric acid. FIG. 7 shows a comparison of the UV-vis absorption spectra of different films. For films without HMT and PEG (TiO₂-1 and TiO₂-2), the absorption is primarily around 340 and 400 nm (FIGS. 7a and 7b). However, for films with HMT (TiO₂-3 and TiO₂-4), the spectra show an obvious red-shift of the absorption edge towards the visible region, with peaks around 350, 426, and 542 nm (FIG. 7c) or 412 nm, 532 nm and an absorption onset at 600 nm (FIG. 7d). FIG. 7e shows the UV-vis absorption spectrum of the TiO₂-3-CdSe film, with strong absorption around 560 nm due to the CdSe QDs. For comparison, FIGS. 8a and 8b show the absorption and photoluminescence (PL) spectra of CdSe QDs in toluene under ambient conditions. The absorption spectrum shows the expected strong and sharp excitonic peak around 560 nm while the PL spectrum shows a narrow emission band near 580 nm, which is clearly due to bandedge emission. FIG. 8c shows the PL spectrum of the TiO₂-3-TGA-CdSe film, with a relatively weak emission peak at 575.5 nm, which is slightly blue shifted with respect to the PL peak of CdSe QDs in toluene solution.

The current-voltage (I-V) profiles for solar cells fabricated using the films with different thicknesses (150 nm and 1100 nm) were obtained using a halogen lamp and a 1 M Na₂S. With the cell configuration shown schematically in FIG. 1, the I-V profiles measured are shown in FIG. 9. The cell without HMT (TiO₂-1-CdSe film) present a low short-circuit current density of −169 μA/cm² with an open-circuit voltage of −1.3V (FIG. 9a) within the voltage window of −1.4 to 0.3 V, and the fill factor is 14.8% with a low power conversion efficiency of η=0.120%. For the cell based on TiO₂-3-TGA-CdSe thin film (150 nm), the I-V curve in FIG. 9b shows a short-circuit current (−242 μA/cm²) with an open-circuit voltage of −1.0 V, a fill factor of 25.4% and power efficiency of η=0.228%. The cell based on TiO₂-3-TGA-CdSe thick film (1100 nm) have the highest short-circuit (−683 μA/cm²) with an open-circuit voltage of 1.2V (FIG. 9c) and the highest fill factor of 27.7% and power conversion efficiency of η=0.840%. Short-circuit current and open circuit voltage found in FIG. 9 is summarized in Table 1.

The fill factor (FF) and power conversion efficiency (η %) were calculated using short-circuit current and open circuit voltage⁴⁵ and are also given in Table 1.

FF=(jVₘₐₓ)/(j_{sc} V_{oc}) (3)

η=(jVₘₐₓ)/Iᵢ=FF(j_{sc} V_{oc})/Iᵢ (4)

where j_{sc} is the short circuit current density, V_{oc} is the open circuit voltage, (jV)ₘₐₓ is the maximum power observed from the current density-voltage curve for each device and Iᵢ is the incident light power density (27 mW/cm²). It is clear that thick films (˜1100 nm) exhibit a higher FF and η % than thin films (˜150 nm). However, cells with TiO₂:N nanoparticles sensitized with CdSe QDs exhibit a much higher η % than films without sensitization.

The incident photon to current conversion efficiency (IPCE) was studied for solid cells and in electrolyte (1M Na₂S) with different thicknesses. IPCE at different wavelengths was determined from the short circuit photocurrent (j_{sc}), where V=0 at different excitation wavelengths (λ) using the expression:

IPCE %=[(1240×j_{sc}(A/cm²)]/[λ(nm)×Iᵢ(w/cm²)]×100 (5)

where I_{inc} is the incident light power. The IPCE results of TiO₂ and TiO₂:N without and with CdSe QDs are shown in FIG. 10. It is clear that the photocurrent response is much stronger with the presence of CdSe QD sensitization. The TiO₂-1-TGA-CdSe film (QD sensitized but without N doping) shows photocurrent responses at 300, 530 and 620 nm, with the highest response near 300 nm with IPCE=56%. The TiO₂-3-TGA-CdSe film (QD sensitized and N-doped) shows similar response but an overall stronger IPCE with the highest response around 95% at 300 nm. The IPCE of both films closely match the absorption spectrum of CdSe QDs, and TiO₂:N as shown in FIG. 7e. The IPCE% is 1.06 at 300 nm for TiO₂:N (magnified 10× in FIG. 10) showing photocurrent responses at 320, 360 and 420 nm also which are close to absorption spectrum as shown in FIG. 7c.

In addition, the IPCE% of TiO₂-3-TGA-CdSe thin film (150 nm) solid cell was studied and the result is shown in FIG. 11. It can be seen that peaks at 480 and 600 nm correspond to absorption of the CdSe QDs (see FIG. 11 inset that shows the absorption and emission spectra of the CdSe nanoparticles in toluene). This cell shows an IPCE response around 6% at 400 nm and the results are summarized in Table 2.

TABLE 2
Summary of IPCE results from our study of thin and thick films based
solar cell in electrolyte (Na₂S) and solid state. Was used a Xenon lamp
(1000 Watts) varying the wavelength with a monochromator.

| Film type | IPCE % (300 nm) |
|---|---|
| TiO₂-1-CdSe | 56 |
| Thick film | |
| TiO₂-2-CdSe | 65 |
| Thick film | |
| TiO₂-3-CdSe | 95 |
| Thick film | |
| TiO₂-4-CdSe | 53 |
| Thick film | |
| TiO₂-4-CdSe | 2.5 |
| Thin film | |
| TiO₂-3 | 1.06 |
| Thick film | |
| TiO₂-3-CdSe | 6 (400 nm) |
| Thin (solid) | |

### Example V

### Synthesis and Analysis of Nanoparticle Films and Nanowires

To understand the synergistic effect between N-doping and CdSe sensitization, we synthesized and studied the PEC properties of both anatase TiO₂ nanoparticle films and vertically aligned rutile TiO₂ nanowire arrays. TiO₂ nanoparticle films were made by spin coating 150 μL of TiO₂ sol-gel nanoparticle solution at 2000 rpm for 1 minute on a piece of fluorine-doped tin oxide (FTO) conductive glass. The films were dried at 50° C. for 30 minutes, followed by repeated coating and drying, and eventually sintered in air at 550° C., as previously described (Guo, B.; Liu, Z.; Hong, L.; Jiang, H.; Lee, J. Y. Thin Solid Films 2005, 479, (1-2), 310-315). TiO₂ nanowire arrays were grown on FTO glass based on a recently reported hydrothermal method with slight modification (Liu, B.; Aydril, E. S. J. Am. Chem. Soc. 2009, 131, 3985-3990). The FTO substrate was placed in a Teflon-lined stainless steel autoclave consisting of a mixture of aqueous solution of titanium n-butoxide and hydrochloric acid. The autoclave was heated in an electric oven at 150° C. for 5 hours, and a uniform film of dense and vertically aligned TiO₂ nanowire arrays on a substrate was obtained. N-doping of the nanomaterial films was achieved by annealing in an ammonia atmosphere at 530° C. using a quartz tube furnace (Yang et al. supra). Films were sensitized with CdSe QDs by chemical bath deposition (CBD) following previously published results (Kale, R. B.; Lokhande, C. D. J. Phys. Chem. B 2005, 109, (43), 20288-20294). A concentrated ammonia solution was added to 10 ml of 0.5 M aqueous solution of Cd(acetate)₂ dihydrate to a pH of 12.5 followed by the slow addition of 30 ml of 0.25 M Na₂SeSO₃ while being stirred for a few minutes. TiO₂ films were placed vertically in the solution at room temperature for about 15 hours to allow deposition of CdSe onto TiO₂.

The resulting TiO₂ nanoparticle films were characterized using electron microscopy and spectroscopy techniques. Scanning electron microscopy (SEM) studies verified that the sintered TiO₂ nanoparticle film has good coverage of the substrate, with a thickness of ˜200 nm. Atomic force microscopy studies confirmed that the film is porous with particles ˜50-100 nm in size. X-ray power diffraction results proved that the sintered TiO₂ nanoparticles have anatase crystal structures. More importantly, there is no phase change after annealing the nanoparticle films in ammonia. After ammonia annealing, the color of the TiO₂ nanoparticle films changed from colorless to pale yellow, suggesting that the incorporation of N introduces bandgap states of TiO₂ and thereby enhances visible light absorption.

To gain a quantitative understanding on the concentration and chemical state of the doped N, we performed X-ray photoelectron spectroscopy (XPS) analysis of the TiO₂ nanoparticle films. High resolution XPS spectrum of the N is region showed three peaks centered at 402.4 eV, 400.0 eV and 397.2 eV respectively. The peaks located at 402.4 eV and 400.0 eV can be ascribed to chemisorbed N₂ and/or amines (NHₓ) originating from ammonia annealing (Asahi et al. supra; Saha, N. C.; Tompkins, H. G. J Appl. Phys. 1992, 72, (7), 3072-3079). The peak at 397.2 eV is typical of the N is binding energy of oxynitride (O—Ti—N), confirming that atomic N atoms incorporate substitutionally at O sites (Vitiello, P. R.; Macak, J. M.; Ghicov, A.; Tsuchiya, H.; Dick, L. F. P.; Schmuki, P. Electrochem. Commun. 2006, 8, 544-548). The atomic percentage for all nitrogen species found in N-doped TiO₂ sample was 1.94%.

Both TiO₂ and N-doped TiO₂ (TiO₂:N) films were sensitized with CdSe QDs using the CBD method. SEM studies showed that the films were coated with very large particles of ˜200 nm in diameter, which were aggregates of smaller CdSe QD. These CdSe aggregates were formed on the surface of the TiO₂ via a “cluster by cluster” growth mechanism (Kale et al. supra; Froment, M.; Lincot, D. Electrochim. Acta 1995, 40, (10), 1293-1303). These CdSe sensitized TiO₂ (CdSe—TiO₂) and N-doped TiO₂ (CdSe—TiO₂:N) nanoparticle films were orange in color due to the strong visible absorption of the CdSe QDs. To quantitatively understand the role of N-doping and CdSe sensitization in electronic transitions in TiO₂ nanoparticle films, their UV-visible absorption spectra were measured, as shown in FIG. 1(13). All spectra show an apparent absorption peak near 325 nm, which was caused by blanking with a conductive FTO glass substrate. For pristine TiO₂, strong absorption starts around 350 nm, and for TiO₂:N slightly increased absorption of visible light appears in the region of 350-520 nm. The electronic energy level due to substitutional N-doping at O sites (Nₒ) has been estimated previously, using Density Functional Theory calculations, to be only 0.14 eV above the valence band of TiO₂ (Di Valentin, C.; Pacchioni, G.; Selloni, A.; Livraghi, S.; Giamello, E. J. Phys. Chem. B 2005, 109, (23), 11414-11419). The increased visible absorption for TiO₂:N is thus not likely to be due to electronic transitions from the Nₒ energy levels to the conduction band of TiO₂. A previous study also indicated that transition from Nₒ to the conduction band of TiO₂, as mainly originating from a N 2P_{π} to Ti d_{xy} transition, is not strong (Tak et al. supra). On the other hand, it has been reported that N-doping facilitates the creation of oxygen vacancies (Vₒ) in TiO₂ lattice (Livraghi, S.; Paganini, M. C.; Giamello, E.; Selloni, A.; Di Valentin, C.; Pacchioni, G. J. Am. Chem. Soc. 2006, 128, (49), 15666-15671; Nambu, A.; Graciani, J.; Rodriguez, J. A.; Wu, Q.; Fujita, E.; Sanz, J. F. J. Chem. Phys. 2006, 125, (9), 094706-094708). In particular, the ammonia annealing process could increase the Vₒ formation, since H₂ generated from as ammonia breakdown at 530° C. can reduce Ti⁴⁺ to Ti³⁺ (oxygen vacancy) (Irie, H.; Watanabe, Y.; Hashimoto, K. J. Phys. Chem. B 2003, 107, (23), 5483-5486; Wang, J.; Tafen, D. N.; Lewis, J. P.; Hong, Z. L.; Manivannan, A.; Zhi, M. J.; Li, M.; Wu, N. Q. J. Am. Chem. Soc. 2009, 131, (34), 12290-12297). The formation of Vₒ creates midgap states about 0.7 - 1.18 eV below the conduction band of TiO₂ (Wang et al. supra; Sanjines, R. T., H. Berger, H. Gozzo, F. Margaritondo, G. Levy, F. J. Appl. Phys. 1993, 75, (6), 2945-2951; Thomas, A. G.; Flavell, W. R.; Kumarasinghe, A. R.; Mallick, A. K.; Tsoutsou, D.; Smith, G. C.; Stockbauer, R.; Patel, S.; Grätzel, M.; Hengerer, R. Phys. Rev. B 2003, 67, (3), 035110; Kuznetsov, V. N.; Serpone, N. J. Phys. Chem. C 2009, 113, (34), 15110-15123). The somewhat enhanced visible light absorption of TiO₂:N is therefore attributed to excitation of electrons from the Nₒ levels to the localized electronic levels of Vₒ. (See Di Valentin et al. supra; Nambu et al. supra; Wang et al. supra; and Serpone, N. J. Phys. Chem. B 2006, 110, (48), 24287-24293.)

In comparison to TiO₂ and TiO₂:N films, CdSe sensitized TiO₂ films exhibit a significant enhancement in absorption of visible light. Both sensitized films showed similar absorption profile with a dominant peak near 525 nm (FIG. 1(13)), which corresponds to the first excitonic absorption of quantum confined CdSe QDs, with an average diameter of nm estimated based on the peak position of the exciton absorption (Yu, W. W.; Qu, L.; Guo, W.; Peng, X. Chem. Mater. 2003, 15, (14), 2854-2860). To the blue of 525 nm, absorption due to transitions to higher electronic states clearly occurs. These excitonic absorptions of CdSe QDs are important for enhancing visible absorption of the CdSe—TiO₂ composites.

### Example VI

### Photoelectrochemical Studies of Nanoparticles

Photoelectrochemical (PEC) cell studies on four TiO₂ nanoparticle films, TiO₂, TiO₂:N, CdSe—TiO₂ and CdSe—TiO₂:N, have been carried out to understand the effect of N-doping and CdSe sensitization on TiO₂ nanoparticle-based photoanode for PEC water splitting. All the PEC studies were conducted in a three-armed cell with a coiled platinum wire as the counter electrode (cathode) and Ag/AgCl double junction reference electrode under nitrogen atmosphere. Photoanodes fabricated from TiO₂ films were made by attaching a copper wire to a bare portion of the FTO conductive glass with a high purity conductive silver paint. Measurements were made on a Solartron 1280B potentiostat using a 1000 W Xenon Arc Lamp as the white light source. The electrolyte used was a mixture of 0.25 M Na₂S and 0.35 M Na₂SO₃ aqueous solution, where Na₂S in solution acts as a hole scavenger and is oxidized into S₂²⁻ to prevent the photocorrosion of CdSe. To ensure efficient hydrogen production at the cathode, Na₂SO₃ was added to reduce disulfides back to sulfides, S₂²⁻+SO₃²⁻→S²⁻+S₂O₃²⁻, which has been shown to significantly increase the amount of hydrogen produced (Banerjee, S.; Mohapatra, S. K.; Das, P. P.; Misra, M. Chem. Mater. 2008, 20, (21), 6784-6791; Buehler, N.; Meier, K.; Reber, J. F. J. Phys. Chem. 2002, 88, (15), 3261-3268; Chi, C. F.; Lee, Y. L.; Weng, H. S. Nanotechnology 2008, 19, (12), 125704).

The linear sweep voltammograms recorded from these samples in the dark and with white light illumination of 100 mW/cm² are shown in FIG. 2(14). The results exhibit several key features. First, all TiO₂ film samples showed a substantial photoresponse, indicating efficient charge separation upon light irradiation. Pristine TiO₂ and TiO₂:N samples showed relatively low steady state photocurrent, ˜25 μA/cm². Pristine TiO₂ is expected to be low due to the limited absorption of visible light. However, it is somewhat surprising that the TiO₂:N sample showed more or less the same maximum photocurrent density as the pristine sample. This can be understood in terms of the N doping energy levels in TiO₂. The observed visible light absorption in TiO₂:N is attributed to the electron excitation from Nₒ levels to Vₒ levels. Since the Vₒ levels are located well below the hydrogen reduction potential (H₂O/H₂), they are not able to result in hydrogen generation and thus enhance the photocurrent, which is consistent with our experimental observation.

Second, both CdSe sensitized samples showed a significant enhancement in photocurrent. CdSe—TiO₂ has a steady state photocurrent density of 0.15 mA/cm² (FIG. 2(14)), which is an order of magnitude enhancement compared to pristine TiO₂ or TiO₂:N. The enhancement is somewhat expected due to strong visible light absorption of CdSe QDs. Significantly, the photocurrent of CdSe—TiO₂:N almost doubles that of CdSe—TiO₂. Since N-doping alone does not noticeably increase the photocurrent and the photocurrent for CdSe—TiO₂:N is much higher than the simple sum of photocurrents for CdSe—TiO₂ and TiO₂:N, a synergistic effect between N-doping and CdSe QD sensitization is clearly in operation and responsible for the enhanced photocurrent in CdS—TiO₂:N compared to CdSe—TiO₂. Due to the importance of this observation, major efforts have been made to ensure validity of comparison and reproducibility of the results with proper control experiments, including film thickness and light intensity.

### Example VII

### Model of Physical Chemistry

To better explain the observed trend in photocurrent density of CdSe—TiO₂:N >CdSe—TiO₂>>TiO₂˜TiO₂:N, we develop a model based on the relevant electronic states of the different components in these composite nanostructures, as shown in FIG. 3(15). The conduction band edge of TiO₂ has been reported to be located at −0.5 eV versus Normal Hydrogen Electrode (NHE), while the conduction band edge of bulk CdSe is close to −0.8 eV versus NHE (Graetzel, M. Nature 2001, 414, 338-344; Wang, C. J.; Shim, M.; Guyot-sionnest, P. Science 2001, 291, 2390-2392). For CdSe QDs, quantum confinement effect makes the energy level of conduction band even more negative (on an NHE scale) with decreasing particle size (Kongkanand, A.; Tvrdy, K.; Takechi, K.; Kuno, M.; Kamat, P. V. J. Am. Chem. Soc. 2008, 130, 4007-4015; Norris, D. J.; Bawendi, M. G. Phys. Rev. B 1996, 53, 16338). This alignment between the conduction band edges of CdSe QDs and TiO₂ nanoparticles should allow for efficient electron transfer from CdSe to TiO₂. Therefore, the photoexcited electrons created in small bandgap CdSe QDs are expected to inject efficiently into TiO₂ nanoparticles and lead to increased photocurrent. More detailed discussion of the model, especially the effect of N-doping, will be given after the IPCE results are disclosed below.

### Example VIII

### Photoresponse Studies

To further quantify the PEC performance, IPCE measurements have been made to study the photoresponse of the TiO₂ nanoparticle samples with and without CdSe sensitization as a function of incident light wavelength. The IPCE was determined at no bias voltage by the equation:

IPCE=(1240×I)/(λ×J_{light}) (6)

where I is the photocurrent density, λ the incident light wavelength, and J_{light} is the measured irradiance. FIG. 4(16) shows the IPCE results for the different TiO₂ nanoparticle films with and without N doping and/or CdSe QD sensitization. The unsensitized samples have strong photoresponse in the near UV region but little photoresponse in >400 nm. In contrast, the sensitized samples show substantial photoactivity in the visible light region from 400 to 600 nm in addition to strong photoresponse in the near UV. These results clearly confirm that CdSe sensitization improves the visible light absorption and the photogenerated electrons in CdSe QD can be transferred to TiO₂. While N-doping has little effect on IPCE for the unsensitized sample, it significantly increases the IPCE throughout the entire visible to near UV region for the QD sensitized sample. This again indicates a clear and significant synergistic effect between QD sensitization and N-doping.

In comparison to the undoped sample, TiO₂:N has a higher density of oxygen vacancy states, Vₒ. It has been proposed that when both Vₒ and N impurities are present in TiO₂, the electrons from occupied 3d states (Ti³⁺) would transfer to lower energy empty 2p states (N²⁻ impurities) (Livraghi et al. supra; Nambu et al. supra; and Torres, G. R.; Lindgren, T.; Lu, J.; Granqvist, C.-G.; Lindquist, S.-E. J. Phys. Chem. B 2004,108, (19), 5995-6003). This electron transfer mechanism is favorable since it simultaneously lower the formation energy of Vₒ and stabilize the N impurities (Livraghi et al. supra; Nambu et al. supra; and Torres et al. supra). We suggest that this electron transfer process results in partially occupied Vₒ levels located at ˜0.4 eV above the CdSe valence band edge (as shown in FIG. 3(15)) that can facilitate hole transfer from CdSe to TiO₂ following photoexcitation of the CdSe QDs. This interfacial hole transfer could improve the PEC photocurrent of CdSe—TiO₂:N nanoparticle films in two ways. First, it can lead to reduction in electron-hole recombination in CdSe QDs. Second, the holes transferred to the Vₒ levels in TiO₂ can either oxidize the sacrificial reagent on site or be further transported through the TiO₂ network to other oxidation sites, the latter being especially important for thick nanocrystalline films. Both processes are expected to lead to enhanced conversion efficiency of light to photocurrent. This explanation is consistent with all the UV-vis and IPCE results. This model is also modified from the previous model we proposed to explain enhanced photoresponse in CdSe—TiO₂:N films for photovoltaic cells where N-doping was thought to directly facilitate hole transport (Lopez-Luke et al. supra). The present novel results strongly suggest that the enhancement in photoresponse for the QD-sensitized and N-doped TiO₂ is due to improved hole transfer/transport enhanced by oxygen vacancy states mediated by N-doping. Detailed kinetic studies on the interfacial carrier transfer between CdSe QD and TiO₂ need to be carried out in the future.

### Example IX

### Photoelectrochemical Studies of Nanowires

To confirm this enhanced hole transfer/transport model first developed for zero-dimensional (OD) TiO₂ nanoparticle films and extend it to one-dimensional (1D) nanostructures, we have also conducted photoelectrochemical (PEC) studies on different TiO₂ nanowire samples (TiO₂, TiO₂:N, CdSe—TiO₂ and CdSe—TiO₂:N). High density and vertically aligned TiO₂ nanowire arrays were grown on FTO glass using a hydrothermal method. Electron microscopy studies showed that the as-prepared nanowires are single crystal rutile structures and are uniform with diameters in the range from ˜100 nm to 150 nm. The typical nanowire lengths are 2 - 3 μm, which depends on the growth time. These TiO₂ nanowire arrays were N-doped in ammonia and sensitized with CdSe QDs using the CBD method, as for TiO₂ nanoparticles. The linear sweep voltammograms recorded from these samples in dark and with light illumination of 100 mW/cm² are illustrated in FIG. 5(17). TiO₂ nanowires exhibit a pronounced photocurrent density of 0.5 mA/cm² at −0.2 V vs. Ag/AgCl. The maximum photocurrent density of TiO₂:N nanowires is similar to that of the pristine sample, as expected. Significantly, both TiO₂ and TiO₂:N nanowire samples showed a great enhancement in photocurrent after CdSe sensitization. In particular, the electrode with the greatest photocurrent density of 2.75 mA/cm² is the CdSe—TiO₂:N nanowires, showing almost two times enhancement compare to CdSe—TiO₂ nanowires. These experimental observations are fully consistent with those obtained for TiO₂ nanoparticle samples in terms of the synergistic effect between QD sensitization and N-doping and indicate that the proposed enhanced hole transfer/transport model is valid for both anatase and rutile TiO₂ nanostructures in 0D or 1D. In addition, it is noted that the TiO₂ nanowire-based photoanodes have almost an order of magnitude higher photocurrent density than that of the TiO₂ nanoparticle-based photoanodes. This enhancement can be attributed to improved vectorial charge transport in 1D structures and/or the increased thickness of nanowire film.

Those skilled in the art will appreciate that various adaptations and modifications of the just-described embodiments can be configured without departing from the scope and spirit of the invention. Other suitable techniques and methods known in the art can be applied in numerous specific modalities by one skilled in the art and in light of the description of the present invention described herein. Therefore, it is to be understood that the invention can be practiced other than as specifically described herein. The above description is intended to be illustrative, and not restrictive. Many other embodiments will be apparent to those of skill in the art upon reviewing the above description. The scope of the invention should, therefore, be determined with reference to the appended claims, along with the full scope of equivalents to which such claims are entitled.

We claim:

1. A thin film structure comprising a conducting substrate, a thin layer comprising nanocrystalline metal oxide doped with nitrogen thereon, and further comprising a semiconductor quantum dot and a linker thereon said thin layer of crystalline metal oxide.

2. The thin film structure of claim 1 wherein the conducting substrate is selected from the group consisting of indium tin oxide and fluorine tin oxide.

3. The thin film structure of claim 1 wherein the nanocrystalline metal oxide is selected from the group consisting of titanium dioxide, tungsten oxide, and zinc oxide.

4. The thin film structure of claim 1 wherein the semiconductor quantum dot is selected from the group consisting of cadmium selenium and cadmium telluride.

5. The thin film structure of claim 1 wherein the linker is selected from the group consisting of thioglycolic acid (TGA), mercaptopropanoic acid (MPA), and cysteine.

6. The thin film structure of claim 1 wherein the linker links the semiconductor quantum dot with the conducting substrate.

7. A photovoltaic cell comprising the thin film structure of claim 1.

8. A hydrogen synthesis system comprising the photovoltaic cell of claim 7.

9. The hydrogen synthesis system of claim 8 further comprising hydrogen storage means wherein the hydrogen is stored therein.

10. The hydrogen synthesis system of claim 9 wherein the hydrogen is stored as a phase selected from the group consisting of a gas, a liquid, and as a liquid or gas in a composition, the composition comprising a plurality of cavities.

11. The photovoltaic cell of claim 7 having a power conversion efficiency of between 1 10⁻³ and 5 η %.

12. The photovoltaic cell of claim 11 having a power conversion efficiency of between 5 10⁻³ and 1 η %.

13. The photovoltaic cell of claim 7 having an incident photon to current conversion efficiency (IPCE) of between 1% and 99%.

14. The photovoltaic cell of claim 13 having an IPCE of between 13% and 95%.

15. The photovoltaic cell of claim 13 having an IPCE of between 25% and 90%.

16. The photovoltaic cell of claim 13 having an IPCE of between 50% and 85%.

17. A method for generating an electric current, the method comprising the steps of (i) providing a conducting substrate; (ii) doping a nanocrystalline metal oxide with nitrogen; (iii) depositing said nanocrystalline metal oxide doped with nitrogen upon said conducting substrate; (iv) providing a semiconductor quantum dot; (v) linking said semiconductor quantum dot to said conducting substrate using a linker; (vi) irradiating the surface of said conducting substrate with photons from a photon source thereby creating or inducing an electric current through the conducting substrate; the method thereby generating an electric current.

18. The method of claim 17 wherein the conducting substrate is selected from the group consisting of indium tin oxide and fluorine tin oxide.

19. The method of claim 17 wherein the crystalline metal oxide is selected from the group consisting of titanium dioxide, tungsten oxide, and zinc oxide.

20. The method of claim 17 wherein the semiconductor quantum dot is selected from the group consisting of cadmium selenium and cadmium telluride.

21. The method of claim 17 wherein the linker is selected from the group consisting of thioglycolic acid (TGA), mercaptopropanoic acid (MPA), and cysteine.

22. The method of claim 17 wherein the photons from the photon source have power intensity of between 1 and 10000 mW/cm².

23. The method of claim 17 wherein the photons from the photon source have power intensity of between 10 and 1000 mW/cm².

24. The method of claim 17 wherein the photons from the photon source have power intensity of between 25 and 250 mW/cm².

25. The method of claim 24 wherein the photons from the photon source have power intensity of 100 mW/cm².

26. The method of claim 24 wherein the photons from the photon source have power intensity of 27 mW/cm².

27. A method for generating hydrogen, the method comprising the steps of (i) providing a conducting substrate; (ii) doping a nanocrystalline metal oxide with nitrogen; (iii) depositing said nanocrystalline metal oxide doped with nitrogen upon said conducting substrate; (iv) providing a semiconductor quantum dot; (v) linking said semiconductor quantum dot to said conducting substrate using a linker; (vi) providing a hydrogen source in contact with the opposing surface of said conducting substrate; (vii) irradiating the surface of said conducting substrate with photons from a photon source thereby creating or inducing an electric current through the conducting substrate; (viii) allowing the electric current to electrolyze the hydrogen source, thereby producing hydrogen; the method thereby generating hydrogen.

28. The method of claim 27 wherein the conducting substrate is selected from the group consisting of indium tin oxide and fluorine tin oxide.

29. The method of claim 27 wherein the crystalline metal oxide is selected from the group consisting of titanium dioxide, tungsten oxide, and zinc oxide.

30. The method of claim 27 wherein the semiconductor quantum dot is selected from the group consisting of cadmium selenium and cadmium telluride.

31. The method of claim 27 wherein the linker is selected from the group consisting of thioglycolic acid (TGA), mercaptopropanoic acid (MPA), and cysteine.

32. The method of claim 27 wherein the hydrogen source is selected from the group consisting of methanol, ethanol, water, formic acid, and an amine compound.

33. The method of claim 27 wherein the photons from the photon source have power intensity of between 1 and 10000 mW/cm².

34. The method of claim 27 wherein the photons from the photon source have power intensity of between 10 and 1000 mW/cm².

35. The method of claim 27 wherein the photons from the photon source have power intensity of between 25 and 250 mW/cm².

36. The method of claim 35 wherein the photons from the photon source have power intensity of 100 mW/cm².

37. The method of claim 35 wherein the photons from the photon source have power intensity of 27 mW/cm².
